(19) United States
(12) Patent Application Publication
(10) Pub. No.: US 2026/0190734 A1
(43) Pub. Date: Jul. 2, 2026

(54) DISPLAY DEVICE

(71) Applicant: LG DISPLAY CO., LTD., SEOUL (KR)

(72) Inventors: Boa Jin, Paju-si (KR); Kimin Lim, Paju-si (KR)

(21) Appl. No.: 19/430,515

(22) Filed: Dec. 23, 2025

(30) Foreign Application Priority Data
Dec. 30, 2024 (KR) 10-2024-0200324

(51) Int. Cl. H10K 59/35; H10K 59/122; H10K 59/65; H10K 59/80

(52) U.S. Cl. CPC H10K 59/353; H10K 59/122; H10K 59/65; H10K 59/80515

(57) ABSTRACT

A display device includes: a substrate including a plurality of subpixels, a first electrode disposed over the substrate, a bank disposed over the substrate, covering a portion of the first electrode, and including an open area, and an infrared emission part disposed over the substrate and at least partially overlapping with the bank, and thereby, is capable of improving the sensing efficiency of an optical sensor by preventing malfunction of the optical sensor.

### CROSS REFERENCE TO RELATED APPLICATION

Pursuant to 35 U.S.C. § 119(a), this application claims the benefit of an earlier filing date and right of priority to Korean Patent Application No. 10-2024-0200324, filed on Dec. 30, 2024 in the Republic of Korea, the entire contents of which are hereby incorporated by reference into the present application.

### TECHNICAL FIELD

The present disclosure relates to an apparatus and particularly to, for example, without limitation, electronic devices, and more specifically, to display devices.

### BACKGROUND

As display technology has advanced, display devices have been developed that can perform functions, such as image capture, sensing, and the like, in addition to image display. To perform these additional functions, display devices can be equipped with optical electronic devices, such as cameras, sensors for detecting images, sensors for detecting light, light receiving devices, and the like.

### SUMMARY

According to one aspect, a display device includes: a substrate including a plurality of subpixels; a first electrode disposed over the substrate; a bank disposed over the substrate, covering a portion of the first electrode and including an open area; and an infrared emission part disposed over the substrate and at least partially overlapping with the bank.

### BRIEF DESCRIPTION OF THE DRAWINGS

The accompanying drawings, which are included to provide a further understanding of the disclosure and are incorporated in and constitute a portion of the disclosure, illustrate implementations of the disclosure and together with the description serve to explain principles of the disclosure. It should therefore be understood that implementations of the present disclosure as described herein are not limited to the illustrations of the accompanying drawings.

FIG. 1 illustrates an example configuration of a display device.

FIG. 2 illustrates an example configuration of the display device.

FIG. 3 illustrates an example system configuration of the display device.

FIG. 4 illustrates an example configuration of a display panel.

FIG. 5 illustrates respective example pixel arrangements of two areas included in a display area of the display panel.

FIG. 6 is a first example cross-sectional view taken along line A-B of FIG. 5.

FIG. 7 is an example cross-sectional view taken along line C-D of FIG. 5.

FIG. 8 is a second example cross-sectional view taken along line A-B of FIG. 5.

FIG. 9 is a third example cross-sectional view taken along line A-B of FIG. 5.

FIG. 10 is a fourth example cross-sectional view taken along line A-B of FIG. 5.

### DETAILED DESCRIPTION

To effectively receive light passing through the front surface of a display device, an optical electronic device can be located in an area of the display device where incident light coming through the front surface can be received and detected. A typical display device can include an optical electronic device located in a front portion of the display device to allow the optical electronic device to be effectively exposed to incident light.

Installing such an optical electronic device (e.g., a camera, a sensor, and the like) in a display device often requires increasing a bezel of the display device or including a notch or a hole in a display area of a display panel of the display device to accommodate the optical electronic device.

It is often desirable for display devices that include optical electronic devices to have a high light transmittance through the front surfaces of the display devices so as to enable the included optical electronic devices to receive or detect incident light and perform their intended functions.

Implementations of the present disclosure are directed to providing a display device that can improve the sensing performance of one or more optical sensors by preventing or reducing the leakage of light due to lateral leakage current (LLC). Such improvements to the sensing performance of the one or more optical sensors can reduce a power consumption of the display device.

For example, by including an infrared emission part (or a near-infrared emission part), implementations of the present disclosure can provide a display device that can prevent or reduce leakage of light due to lateral leakage current (LLC), prevent or reduce malfunctions of one or more optical sensors of the display device, and improve an efficiency of sensing external light by the one or more optical sensors of the display device.

Effects or advantages of implementation of the present disclosure are not limited thereto, and additional effects or advantages will become apparent to those skilled in the art from the following description.

It is to be understood that both the foregoing general description and the following detailed description are exemplary and explanatory and are intended to provide further explanation of the inventive concepts as claimed.

Reference will now be made in detail to example implementations of the present disclosure, implementations of which are illustrated in the accompanying drawings. In the following description, the structures, implementations, methods, and operations described herein are not limited to the specific examples and implementations set forth herein and can be changed as is known in the art, unless otherwise specified. Like reference numerals designate like elements throughout, unless otherwise specified. Names of the respective elements used in the following explanations are selected only for convenience of writing the specification and can thus be different from those used in actual products. Advantages and features of the present disclosure, and implementation methods thereof will be clarified through following example implementations described with reference to the accompanying drawings. The present disclosure can, however, be embodied in different forms and should not be construed as limited to the example implementations set forth herein. Rather, these example implementations are provided so that this disclosure is sufficiently thorough and complete to assist those skilled in the art to fully understand the scope of the present disclosure. Further, the protected scope of the present disclosure is defined by claims and their equivalents. In the following description, where the detailed description of the relevant known function or configuration might unnecessarily obscure aspects of the present disclosure, a detailed description of such known function or configuration may be omitted. The shapes, sizes, ratios, angles, numbers, and the like, which are illustrated in the drawings to describe various example implementations of the present disclosure, are merely given by way of example. Therefore, the present disclosure is not limited to the illustrations in the drawings. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts”, “overlaps with”, or the like a second element, it should be interpreted that, not only can the first element “be directly connected or coupled to”, “directly contact”, or “directly overlap with” the second element, but a third element can also be “interposed” between the first and second elements, or the first and second elements can “be connected or coupled to”, “contact”, “overlap with”, or the like each other via a fourth element. Here, the second element can be included in at least one of two or more elements that “are connected or coupled to”, “contact”, “overlap with”, or the like each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, and the like) include a tolerance or error range that can be caused by various factors (e.g., process factors, internal or external impact, noise, and the like) even when a relevant description is not specified. Further, the term “may” fully encompasses all the meanings of the term “can”.

In the following description, various example implementations of the present disclosure are described in detail with reference to the accompanying drawings. With respect to reference numerals to elements of each of the drawings, the same elements can be illustrated in other drawings, and like reference numerals refer to like elements unless stated otherwise. The same or similar elements can be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, implementations of the present disclosure are not limited to a scale, dimension, size, and thickness illustrated in the drawings.

Any implementation described herein as an “example” is not necessarily to be construed as preferred or advantageous over other implementations.

In describing a temporal relationship, when the temporal order is described as, for example, “after,” “subsequent,” “next,” and “before,” a case that is not continuous can be included unless a more limiting term, such as “just,” “immediate(ly),” or “direct(ly)” is used.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Features of various implementations of the present disclosure can be partially or overall coupled to or combined with each other, and can be variously inter-operated with each other and driven technically as those skilled in the art can sufficiently understand. Implementations of the present disclosure can be carried out independently from each other, or can be carried out together in co-dependent relationship.

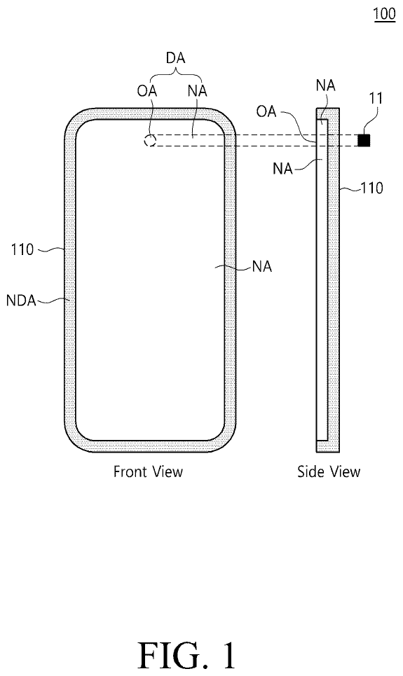

FIG. 1 illustrates an example configuration of a display device 100.

Referring to FIG. 1, the display device 100 can include a display panel 110 configured to display an image, and one or more optical electronic devices 11. Herein, an optical electronic device can be referred to as a light detector, a light receiver, or a light sensing device. An optical electronic device can include one or more of a camera, a camera lens, a sensor, a sensor for detecting images, or the like.

The display panel 110 can include a display area DA in which one or more images can be displayed and a non-display area NDA in which an image is not displayed.

A plurality of subpixels can be disposed in the display area DA, and several types of signal lines for driving the plurality of subpixels can be disposed therein.

The non-display area NDA can be an area outside of the display area DA. Several types of signal lines can be disposed in the non-display area NDA, and several types of driving circuits can be connected thereto. At least a portion of the non-display area NDA can be bent, and thereby, be invisible in front of the display device 100 or be covered by a case or housing (not shown) of the display device 100. The non-display area NDA can be also referred to as a non-active area, a bezel, or a bezel area.

Referring to FIG. 1, in some implementations, the optical electronic device 11 can be an electronic device located under, or at a lower portion of, the display panel 110 (an opposite side to the viewing surface thereof).

Light can enter the front surface (the viewing surface) of the display panel 110, pass through the display panel 110, reach the optical electronic device 11 located under, or at the lower portion of, the display panel 110 (the opposite side of the viewing surface). Light passing through the display panel 110 can include, for example, visible light, infrared light, ultraviolet light, or the like.

The optical electronic device 11 can be a device capable of receiving or detecting light passing through the display panel 110 and perform a predefined function based on the received light. For example, the optical electronic device 11 can include one or more of the following: an image capture device such as a camera, an image sensor, and/or the like; or a sensor such as a proximity sensor, an illuminance sensor, and/or the like. For example, the illuminance sensor can be, but is not limited to, an ambient light sensor.

Referring to FIG. 1, in some implementations, the display area DA of the display panel 110 can include one or more optical areas OA and a normal area NA. Herein, the term “normal area” NA can be an area that while being present in the display area DA, does not overlap with one or more optical electronic devices 11 and can also be referred to as a non-optical area. For example, the optical area OA can be an area overlapping with the optical electronic device 11 in a cross-sectional view of the display panel 110.

FIG. 1 illustrates that the optical area OA has a circular shape, but implementations of the present disclosure are not limited thereto. For example, the optical area OA can have various shapes such as an elliptical oval, square, hexagonal, or octagonal shape.

In some implementations, the optical area OA can include both an image display structure and a light transmissive structure. For example, since the optical area OA is included in the display area DA, corresponding light emitting areas of subpixels for displaying images can be disposed in the optical area OA. Further, to enable the optical electronic device 11 to fully receive light, the optical area OA can include a light transmissive structure.

The normal area NA and the optical area OA can have a same function of allowing an image to be presented. However, the normal area NA can be an area in which a light transmissive structure need not be implemented, and the optical area OA can be an area in which a light transmissive structure need be implemented.

Accordingly, the optical area OA can have a transmittance greater than or equal to a predetermined level, i.e., a relatively high transmittance, and the normal area NA can have a transmittance less than the predetermined level or not have light transmittance.

For example, the optical area OA can have a resolution, a subpixel arrangement structure, the number of subpixels per unit area, an electrode structure, a line structure, an electrode arrangement structure, a line arrangement structure, or/and the like different from that/those of the normal area NA.

For example, the number of subpixels per unit area in the optical area OA can be less than the number of subpixels per unit area in the normal area NA. For example, the resolution of the optical area OA can be lower than that of the normal area NA. Here, the number of subpixels per unit area can have the same meaning as resolution, density of pixels, or integration degree of pixels. For example, the number of subpixels per unit area can be represented as pixels per inch (PPI), which represents the number of pixels in one inch.

In some implementations, the display device 100 or the display panel 110 can have a design scheme where different pixel sizes are applied to the optical area OA and the nominal area NA (which can be referred to as a different pixel size applying design). According to the different pixel size applying design, the display device 100 or the display panel 110 can be designed such that the number of subpixels per unit area of the optical area OA is equal to or similar to the number of subpixels per unit area of the normal area NA, but the size of each subpixel SP disposed in the optical area OA (e.g., the size of a corresponding light emitting area) is smaller than the size of each subpixel SP disposed in the normal area NA (e.g., the size of a corresponding light emitting area).

Herein, the display device 100 having a structure in which the optical electronic device 11 such as a camera, and the like. is located under, or at a lower portion of, the display panel 110 without being exposed to the outside can be referred to as a display in which under-display camera (UDC) technology is implemented.

According to this structure, the display device 100 can provide an advantage of preventing a size of the display area DA from being reduced because a notch or a camera hole for exposing a camera need not be formed in the display panel 110. Indeed, since a notch or a camera hole for camera exposure need not be formed in the display panel 110, the display device 100 can provide further advantages of reducing a size of a bezel area, and improving the degree of freedom in design because such limitations to the design are removed.

Although the optical electronic device 11 is located under, or at a lower portion of, the display panel 110 of the display device 100 (e.g., hidden or not to be exposed to the outside), the optical electronic device 11 is needed to normally receive or detect light, and thereby, perform a predefined functionality.

Further, although the optical electronic device 11 included in the display device 100 is located under, or at a lower portion of, the display panel 110 to be hidden and located to be overlapped with the display area DA, it is necessary for image display to be normally performed in the optical area OA overlapping with the optical electronic device 11 in the display area DA.

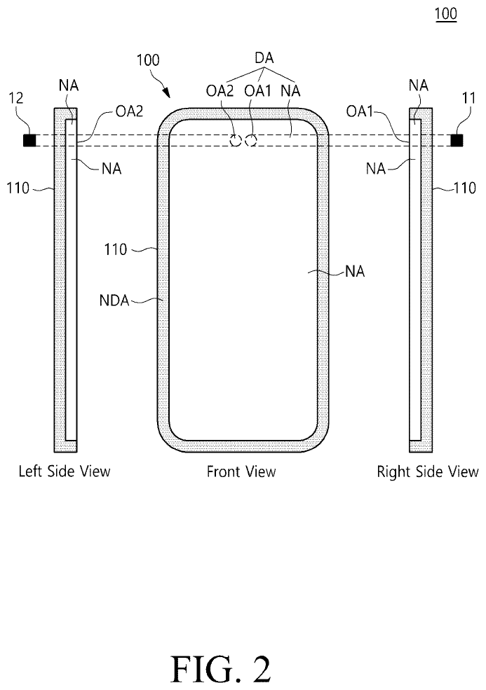

FIG. 2 illustrates an example configuration of the display device 100. In discussions that follow for configuration of FIG. 2, discussions for features and examples equal, substantially equal, or similar to the features and examples described with reference to FIG. 1 are omitted or briefly described for convenience of description.

Referring to FIG. 2, the display device 100 can include the display panel 110 for displaying an image, and one or more optical electronic devices (11 and/or 12).

The one or more optical electronic devices (11 and/or 12) can be devices capable of receiving or detecting light passing through the display panel 110 and perform a predefined function based on the received light. For example, the one or more optical electronic devices (11 and/or 12) can include one or more of the following: an image capture device such as a camera, an image sensor, and/or the like; or a sensor such as a proximity sensor, an illuminance sensor, and/or the like.

Referring to FIG. 2, in some implementations, the display area DA of the display panel 110 can include one or more optical areas (OA1 and/or OA2) and a normal area NA. The one or more optical areas (OA1 and/or OA2) can be one or more areas respectively overlapping with the one or more optical electronic devices (11 and/or 12) in plan view.

In some implementations, the one or more optical areas (OA1 and/or OA2) can include both an image display structure and a light transmissive structure. For example, since the one or more optical areas (OA1 and/or OA2) are included in the display area DA, corresponding light emitting areas of subpixels for displaying images can be disposed in the one or more optical areas (OA1 and/or OA2). Further, to enable the one or more optical electronic devices (11 and/or 12) to fully receive light, the one or more optical areas (OA1 and/or OA2) can include a light transmissive structure.

In some implementations, the one or more optical electronic devices (11 and/or 12) can include a first optical electronic device 11 and a second optical electronic device 12. For example, the first optical electronic device 11 can be an image capture device such as a camera, an image sensor, and the like, and the second optical electronic device 12 can be a sensor such as a proximity sensor, an illuminance sensor, and the like. In another example, the first optical electronic device 11 can be a sensor such as a proximity sensor, an illuminance sensor, and the like, and the second optical electronic device 12 can be an image capture device such as a camera, an image sensor, and the like. Hereinafter, for convenience of description, discussions are provided based on examples where the first optical electronic device 11 is an image capture device such as a camera, an image sensor, and the like, and the second optical electronic device 12 is a sensor such as a proximity sensor, an illuminance sensor, and the like. It should be, however, understood that the scope of the present disclosure includes examples where the first optical electronic device 11 is the sensor, and the second optical electronic device 12 is the image capture device. The camera can be, for example, a camera lens, an image sensor, or a unit including at least one of the camera lens and the image sensor.

The one or more optical areas (OA1 and/or OA2) can include a first optical area OA1 and a second optical area OA2. The first optical area OA1 can have various shapes, such as a circle, an ellipse, a quadrangle, a hexagon, an octagon or the like. The second optical area OA2 can have various shapes, such as a circle, an ellipse, a quadrangle, a hexagon, an octagon or the like. The first optical area OA1 and the second optical area OA2 can have the same or substantially or nearly the same shape, or different shapes.

Further, in some implementations, while the first optical area OA1 and the second optical area OA2 included in the display device 100 are light transmissive areas having similar functions, the first optical area OA1 and the second optical area OA2 can be used in different applications. Therefore, the first optical area OA1 and the second optical area OA2 included in the display device 100 can be designed to have different structures from each other.

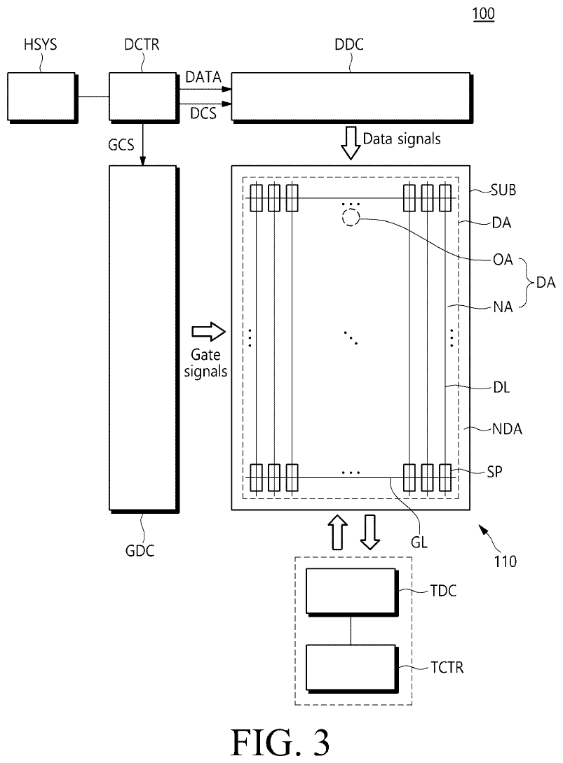

FIG. 3 illustrates an example system configuration of the display device 100. In discussions that follow for the configuration of FIG. 3, discussions for features and examples equal, substantially equal, or similar to the features and examples described with reference to FIGS. 1 and 2 are omitted or briefly described for convenience of description.

Referring to FIG. 3, in some implementations, the display device 100 can include the display panel 110 and at least one display driving circuit as components for displaying an image. The display panel 110 can correspond to the display panel 110 of FIG. 1, or the display panel 110 of FIG. 1 can be applied to the configuration of FIG. 3.

The at least one display driving circuit can be a circuit for driving the display panel 110, and include a data driving circuit DDC, a gate driving circuit GDC, a display controller DCTR, and other circuit components.

The display panel 110 can include a substrate SUB and a plurality of subpixels SP disposed on the substrate SUB. The display panel 110 can further include several types of signal lines to drive the plurality of subpixels SP.

In some implementations, the display device 100 can be a liquid crystal display device, or the like, or a self-emissive display device in which light is emitted from the display panel 110 itself. In an example where the display device 100 is the self-emissive display device, each of a plurality of subpixels SP included in the display panel 110 can include a light emitting element.

For example, in some implementations the display device 100 can be an organic light emitting display device in which light emitting elements are implemented using organic light emitting diodes (OLED). As another example, the display device 100 can be an inorganic light emitting display device in which light emitting elements are implemented using inorganic material-based light emitting diodes. As another example, the display device 100 can be a quantum dot display device in which the light emitting element is implemented using quantum dots, which are self-emission semiconductor crystals.

The structure of each of the plurality of subpixels SP can be differently configured or designed according to types of the display device 100. For example, when the display device 100 is a self-emissive display device including self-emissive subpixels SP, each subpixel SP can include a self-emissive light emitting element, one or more transistors, and one or more capacitors.

Several types of signal lines can be disposed in the display device 100, including, for example, a plurality of data lines DL for delivering data signals (which can be referred to as data voltages or image signals), a plurality of gate lines GL for delivering gate signals (which can be referred to as scan signals), and the like.

The plurality of data lines DL and the plurality of gate lines GL can intersect each other. Each of the plurality of data lines DL can extend in a first direction. Each of the plurality of gate lines GL can extend in a second direction different from the first direction.

For example, the first direction can be the column or vertical direction, and the second direction can be the row or horizontal direction. In another example, the first direction can be the row or horizontal direction, and the second direction can be the column or vertical direction.

The data driving circuit DDC can be a circuit for driving the plurality of data lines DL, and can supply data signals to the plurality of data lines DL. The gate driving circuit GDC can be a circuit for driving the plurality of gate lines GL, and can supply gate signals to the plurality of gate lines GL.

The display controller DCTR can be a device for controlling the data driving circuit DDC and the gate driving circuit GDC, and can control driving times for the plurality of data lines DL and driving times for the plurality of gate lines GL.

The display controller DCTR can supply a data driving control signal DCS to the data driving circuit DDC to control the data driving circuit DDC, and supply a gate driving control signal GCS to the gate driving circuit GDC to control the gate driving circuit GDC.

The display controller DCTR can receive input image data from a host system HSYS and supply image data DATA readable by the data driving circuit DDC based on the input image data to the data driving circuit DDC.

The data driving circuit DDC can supply data signals to the plurality of data lines DL according to driving timing control of the display controller DCTR.

The data driving circuit DDC can receive digital image data DATA from the display controller DCTR, convert the received image data DATA into analog data signals, and output the resulting analog data signals to the plurality of data lines DL.

The gate driving circuit GDC can supply gate signals to the plurality of gate lines GL according to timing control of the display controller DCTR. The gate driving circuit GDC can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

The data driving circuit DDC can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

In some implementations, the gate driving circuit GDC can be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. In some implementations, the gate driving circuit GDC can be disposed in the non-display area NDA of the display panel 110 by a gate-in-panel (GIP) technique. The gate driving circuit GDC can be disposed on the substrate, or connected to the substrate. In an example where the gate driving circuit GDC is implemented by the GIP technique, the gate driving circuit GDC can be disposed in the non-display area NDA of the substrate. The gate driving circuit GDC can be connected to the substrate in an example where the gate driving circuit GDC is implemented by the chip-on-glass (COG) technique, the chip-on-film (COF) technique, or the like.

In some implementations, at least one of the data driving circuit DDC and the gate driving circuit GDC can be disposed in the display area DA of the display panel 110. For example, at least one of the data driving circuit DDC and the gate driving circuit GDC can be disposed so as not to overlap with subpixels SP, or disposed to overlap with one or more, or all, of the subpixels SP, or at least respective one or more portions of one or more subpixels.

In some implementations, the data driving circuit DDC can be disposed in, and/or electrically connected to, but not limited to, only one side or edge (e.g., an upper portion or a lower portion) of the display panel 110. In some implementations, the data driving circuit DDC can be located in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

In some implementations, the gate driving circuit GDC can be located in, and/or electrically connected to, but not limited to, one side or edge (e.g., a left portion or a right portion) of the display panel 110. In some implementations, the gate driving circuit GDC can be located in, and/or electrically connected to, but not limited to, two sides or edges (e.g., a left portion and a right portion) of the panel 110 or at least two of four sides or edges (e.g., an upper portion, a lower portion, the left portion, and the right portion) of the panel 110 according to driving schemes, panel design schemes, or the like.

The display controller DCTR can be implemented in a separate component from the data driving circuit DDC, or integrated with the data driving circuit DDC, so that the display controller DCTR and the data driving circuit DDC can be implemented in a single integrated circuit.

The display controller DCTR can be a timing controller used in the normal display technology or a controller or a control device capable of performing other control functions in addition to the function of the normal timing controller. In some implementations, the display controller DCTR can be a controller or a control device different from the timing controller, or a circuitry or a component included in the controller or the control device. The display controller DCTR can be implemented with various circuits or electronic components such as an integrated circuit (IC), a field programmable gate array (FPGA), an application specific integrated circuit (ASIC), a processor, and/or the like.

The display controller DCTR can be mounted on a printed circuit board, a flexible printed circuit, or the like, and can be electrically connected to the data driving circuit DDC and the gate driving circuit GDC through the printed circuit board, the flexible printed circuit, and/or the like.

The display controller DCTR can transmit signals to, and receive signals from, the data driving circuit DDC via one or more predefined interfaces. For example, such interfaces can include, a low voltage differential signaling (LVDS) interface, an embedded clock point-point interface (EPI), a serial peripheral interface (SP), and the like.

In some implementations, to further provide a touch sensing function as well as an image display function, the display device 100 can include at least one touch sensor, and a touch sensing circuit capable of detecting whether a touch event occurs by a touch object such as a finger, a pen, or the like, or of detecting a corresponding touch position, by sensing the touch sensor.

The touch sensing circuit can include a touch driving circuit TDC capable of generating and providing touch sensing data by driving and sensing the touch sensor, a touch controller TCTR capable of detecting the occurrence of a touch event or detecting a touch position (or touch coordinates) using the touch sensing data, and one or more other components.

The touch sensor can include a plurality of touch electrodes. The touch sensor can further include a plurality of touch lines for electrically connecting the plurality of touch electrodes to the touch driving circuit TDC.

The touch sensor can be implemented in the form of a touch panel outside of the display panel 110 or be integrated inside of the display panel 110. In the example where the touch sensor is implemented in the form of the touch panel outside of the display panel 110, such a touch sensor can be referred to as an add-on type. In the example where the add-on type of touch sensor is disposed in the display device 100, the touch panel and the display panel 110 can be separately manufactured and combined in an assembly process. The add-on type of touch panel can include a touch panel substrate and a plurality of touch electrodes disposed on the touch panel substrate.

In the example where the touch sensor is integrated inside of the display panel 110, the touch sensor can be formed on the substrate SUB together with signal lines and electrodes related to display driving during a process of manufacturing the display panel 110.

The touch driving circuit TDC can supply a touch driving signal to at least one of a plurality of touch electrodes, and sense at least one of the plurality of touch electrodes to generate touch sensing data.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on a capacitance between one or more touch electrodes and an object such as a finger, a pen, and/or the like.

According to the self-capacitance sensing technique, each of a plurality of touch electrodes can serve as both a driving touch electrode and a sensing touch electrode. The touch driving circuit TDC can drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes.

According to the mutual-capacitance sensing technique, a plurality of touch electrodes can be divided into driving touch electrodes and sensing touch electrodes. The touch driving circuit TDC can drive the driving touch electrodes and sense the sensing touch electrodes.

In some implementations, the touch driving circuit TDC and the touch controller TCTR, which are included in the touch sensing circuit, can be implemented in separate devices or in one device. In some implementations, the touch driving circuit TDC and the data driving circuit DDC can be implemented in separate devices or in one device.

The display device 100 can further include a power supply circuit for supplying several types of power to the display driving circuit and/or the touch sensing circuit.

In some implementations, the display device 100 can be a mobile terminal such as a smart phone, a tablet, or the like, or a monitor, a television (TV), or the like. Further, the display device 100 can be configured with various types, sizes, and shapes to display information or images. For example, the display device 100 can be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

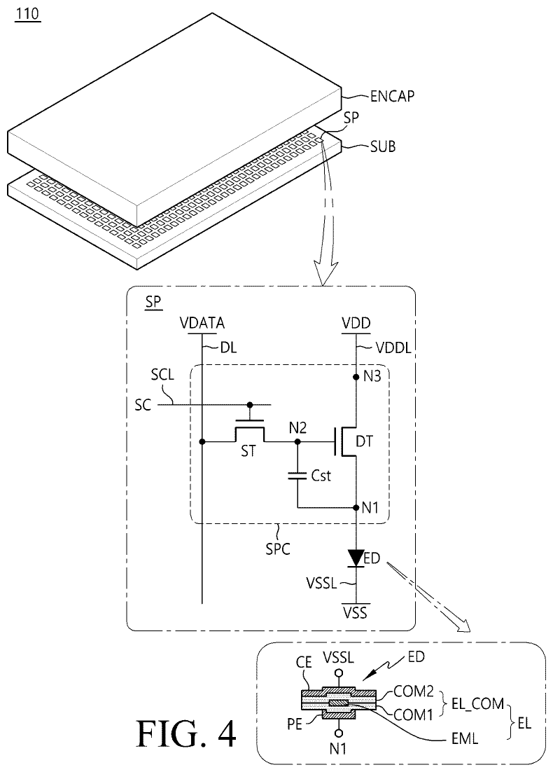

FIG. 4 is an example configuration of the display panel 110. In discussions that follow for the configuration of FIG. 4, discussions for features and configurations equal, substantially equal, or similar to the features and configurations described with reference to FIGS. 1 to 3 are omitted or briefly described for convenience of description.

Referring to FIG. 4, the display panel 110 can include a substrate SUB on which a plurality of subpixels SP are disposed, and an encapsulation layer ENCAP over the substrate SUB. The encapsulation layer ENCAP can also be referred to as an encapsulation substrate or an encapsulation part.

Referring to FIG. 4, in an example where the display device 100 is a self-emissive display device, each of the plurality of subpixels SP disposed on the substrate SUB can include a light emitting element ED and a subpixel circuit SPC for driving the light emitting element ED.

Referring to FIG. 4, the subpixel circuit SPC can include a plurality of transistors and at least one capacitor for driving the light emitting element ED. The subpixel circuit SPC can drive the light emitting element ED by supplying a driving current to the light emitting element ED at a predetermined time. The light emitting element ED can emit light by being driven by the driving current.

The plurality of transistors can include a driving transistor DT configured to drive the light emitting element ED and a scan transistor ST configured to be turned on or off by a scan signal SC.

The driving transistor DT can supply a driving current to the light emitting element ED.

The scan transistor ST can be configured to control an electrical state of a corresponding node in the subpixel circuit SPC or to control the state or operation of the driving transistor DT.

The at least one capacitor can include a storage capacitor Cst configured to maintain a voltage at a constant level during a display frame or a period of the display frame.

To drive at least one subpixel SP, at least one data signal VDATA, which is an image signal, and at least one scan signal SC, which is a gate signal, can be applied to the at least one subpixel SP. Further, to drive one or more subpixels SP, at least one common driving voltage including a first common driving voltage VDD and a second common driving voltage VSS can be applied to the one or more subpixels SP.

The light emitting element ED can include a pixel electrode PE, an intermediate layer EL, and a common electrode CE. The intermediate layer EL can be disposed between the pixel electrode PE and the common electrode CE.

For example, the pixel electrode PE can be an electrode disposed for each subpixel SP, and the common electrode CE can be an electrode disposed commonly in all or some of a plurality of subpixels SP. For example, the pixel electrode PE can be an anode, and the common electrode CE can be a cathode. In another example, the pixel electrode PE can be a cathode, and the common electrode CE can be an anode. Hereinafter, for convenience of explanation, discussions can be provided based on examples where the pixel electrode PE is an anode, and the common electrode CE is a cathode.

In an example where the light emitting element ED is an organic light emitting diode, the intermediate layer EL can include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 can be referred to as a common intermediate layer EL_COM.

In some implementations, the emission layer EML can be disposed for each subpixel SP, and the common intermediate layer EL_COM can be commonly disposed across all or some of a plurality of subpixels SP.

The emission layer EML can be disposed for each light emitting area, and the common intermediate layer EL_COM can be disposed commonly across all or some of a plurality of light emitting areas and all or some of a plurality of non-light emitting areas.

For example, the first common intermediate layer COM1 can include a hole injection layer HIL, a hole transfer layer HTL, and the like. The second common intermediate layer COM2 can include an electron transport layer ETL, an electron injection layer EIL, and the like.

The hole injection layer can inject holes from the pixel electrode PE to the hole transport layer, the hole transport layer can transport holes to the emission layer EML. The electron injection layer can inject electrons from the common electrode CE to the electron transport layer, and the electron transport layer can transport electrons to the emission layer EML.

In some implementations, the common electrode CE can be electrically connected to a second common driving voltage line VSSL. A second common driving voltage VSS can be applied to the common electrode CE through the second common driving voltage line VSSL. The pixel electrode PE can be electrically connected directly or indirectly (via another transistor) to a first node N1 of the corresponding driving transistor DT of each subpixel SP. Herein, the second common driving voltage VSS can also be referred to as a “base voltage”, and the second common driving voltage line VSSL can also be referred to as a “low power supply voltage line”, a “low voltage line”, or a “base voltage line.

Each light emitting element ED can be configured by overlapping of a pixel electrode PE, an emission layer EML in an intermediate layer EL, and a common electrode CE. A respective light emitting area can be formed by each light emitting element ED. For example, a respective light emitting area of each light emitting element ED can include an area where a pixel electrode PE, an emission layer EML in an intermediate layer EL, and a common electrode CE overlap with each other.

In some implementations, each or at least one of a plurality of light emitting elements ED included in the display panel 110 or the display device 100 can be an organic light emitting diode (OLED), an inorganic light emitting diode (LED), a quantum dot (QD) light emitting element, a micro light emitting diode, a mini light emitting diode, or the like, but implementations of the present disclosure are not limited thereto. In the example where each light emitting element ED is an organic light emitting diode (OLED), the intermediate layer EL of a corresponding light emitting element ED can be a layer including an organic material.

Referring to FIG. 4, the driving transistor DT can be a transistor configured to supply a driving current to the light emitting element ED. The driving transistor DT can be connected between a first common driving voltage line VDDL and the light emitting element ED.

The driving transistor DT can include a first node N1, a second node N2, and a third node N3. The first node N1 can be electrically connected to the light emitting element ED. A data signal VDATA can be applied to the second node N2. A first common driving voltage VDD delivered through the first common driving voltage line VDDL can be applied to the third node N3.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes (or electrodes), respectively. However, implementations of the present disclosure are not limited thereto.

The scan transistor ST included in the subpixel circuit SPC illustrated in FIG. 4 can be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst can be an external capacitor intentionally designed to be located outside of the driving transistor DT, and therefore, be different from an internal capacitor such as a parasitic capacitor (e.g., a Cgs, a Cgd) that can be formed between the first node N1 and the second node N2 of the driving transistor DT.

Each of the driving transistor DT and the scan transistor ST can be an n-type transistor or a p-type transistor.

The display panel 110 can have a top emission structure or a bottom emission structure.

In an example where the display panel 110 has the top emission structure, at least a portion of the subpixel circuit SPC can be overlapped with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC can be located without overlapping the light emitting element ED in the vertical direction.

The subpixel circuit SPC can have a 2T (Transistor) 1C (Capacitor) structure including two transistors (DT and ST) and one capacitor (Cst) as illustrated in FIG. 4. In some implementations, the subpixel circuit SPC can further include one or more transistors or one or more capacitors in the 2T1C structure.

For example, the subpixel circuit SPC can have an 8T1C structure including 8 transistors and 1 capacitor. In another example, the subpixel circuit SPC can have an 6T2C structure including 6 transistors and 2 capacitor. In another example, the subpixel circuit SPC can have an 7T1C structure including 7 transistors and 1 capacitor. However, implementations of the present disclosure are not limited to such specific structures.

The types and number of gate signals supplied to a subpixel SP, and/or the types and number of gate lines connected to the subpixel SP can vary depending on a structure of a corresponding subpixel circuit SPC. Further, the types and number of common driving voltages supplied to a subpixel SP can vary depending on a structure of a corresponding subpixel circuit SPC.

Referring to FIG. 4, since circuit elements (e.g., a light emitting element ED such as an organic light emitting diode (OLED) including an organic material) in each subpixel SP can be easily damaged by external moisture or oxygen, an encapsulation layer ENCAP can be disposed in the display panel 110 to prevent or at least reduce the external moisture or oxygen from penetrating the circuit elements (e.g., the light emitting element ED).

The encapsulation layer ENCAP can be disposed in various shapes or configurations to prevent or at least reduce light emitting elements ED from contacting moisture or oxygen. For example, the encapsulation layer ENCAP can include two or more layers in which one or more organic layers and one or more inorganic layers are alternately stacked, but implementations of the present disclosure are not limited thereto.

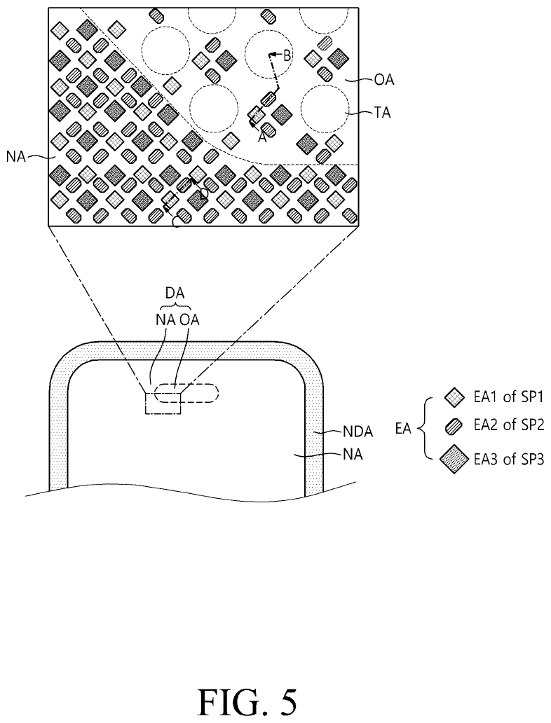

FIG. 5 illustrates respective example pixel arrangements of two areas included in a display area (normal area NA and optical area OA) of the display panel 110. In discussions that follow for the configuration of FIG. 5, discussions for features and configurations equal, substantially equal, or similar to the features and configurations described with reference to FIGS. 1 to 4 are omitted or briefly described for convenience of description.

Referring to FIG. 5, a plurality of subpixels SP can be disposed in each of the normal area NA, and an optical area OA (e.g., the optical area OA of FIG. 1, or the first optical area OA1 or the second optical area OA2 of FIG. 2) included in the display area DA.

For example, the plurality of subpixels SP can include a first subpixel SP1, a second subpixel SP2, and a third subpixel SP3. The first subpixel SP1 can include a red subpixel emitting red light, the second subpixel SP2 can include a green subpixel emitting green light, and the third subpixel SP3 can include a blue subpixel emitting blue light.

Accordingly, each of the normal area NA and the optical area OA can include light emitting areas EA1 of the first subpixels SP1, light emitting areas EA2 of the second subpixels SP2, and light emitting areas EA3 of the third subpixels SP3.

Referring to FIG. 5, in some implementations, the normal area NA does not include a light transmissive structure, but can include light emitting areas EA.

In contrast, the optical area OA can include not only light emitting areas EA, but also a light transmissive structure. Therefore, the optical area OA can include light emitting areas EA and transmissive areas TA.

The light emitting areas EA and the transmissive areas TA can be distinguished based on whether light is allowed to be transmitted or not. For example, the light emitting areas EA can be areas that do not allow light to be transmitted, and the transmissive areas TA can be areas that do allow light to be transmitted.

Further, the light emitting areas EA and the transmissive areas TA can be distinguished based on whether a second electrode CE is disposed or not. For example, in some implementations, a second electrode CE can be disposed in the light emitting areas EA and not disposed in the transmissive areas TA.

Further, in some implementations, a light shield (or a light shielding layer) can be disposed in the light emitting areas EA and not disposed in the transmissive areas TA.

Since the optical area OA includes the transmissive areas TA, the optical area OA is an area allowing light to be transmitted. In some implementations, the optical area OA can include the first optical area OA1 and the second optical area OA2. The first optical area OA1 can include at least one first transmissive area, and the second optical area OA2 can include at least one second transmissive area.

A transmittance (a degree of transmission) of the first optical area OA1 and a transmittance (a degree of transmission) of the second optical area OA2 can be substantially the same or different from each other. Herein, being substantially the same can mean the same degree, taking into account a slight difference due to an error in the process.

FIG. 5 illustrates that the transmissive areas TA of the optical area OA have a circular shape in cross-section, but implementations of the present disclosure are not limited thereto.

For example, the transmissive areas TA of the optical area OA can have an octagonal shape in a plan view, or an oval or polygonal shape.

According to this configuration, the area of the light emitting areas of the optical area OA can be adjusted by adjusting the transmittance of the transmissive areas TA through a change in the shape of the transmissive areas TA.

Referring to FIG. 5, in some implementations, the transmissive areas TA can also be referred to as transparent areas, and the transmittance can also be referred to as transparency.

As illustrated in FIG. 5, it is assumed that the optical area OA is disposed in an upper edge of the display area DA of the display panel 110, as one example.

A plurality of subpixels SP can include the first subpixel SP1 emitting red light, the second subpixel SP2 emitting green light, and the third subpixel SP3 emitting blue light, and a single unit pixel can be formed by including two or more of the first subpixel SP1 emitting red light, the second subpixel SP2 emitting green light, and the third subpixel SP3 emitting blue light.

In some implementations, the plurality of subpixels SP can further include at least one white subpixel.

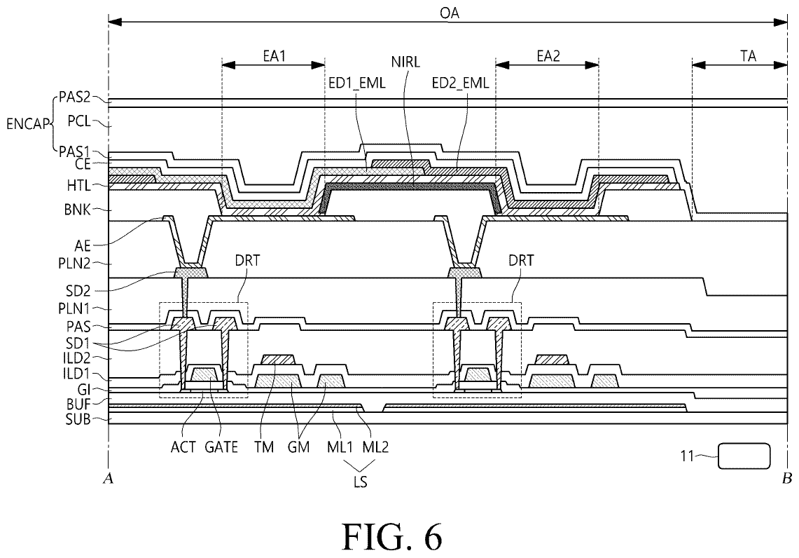

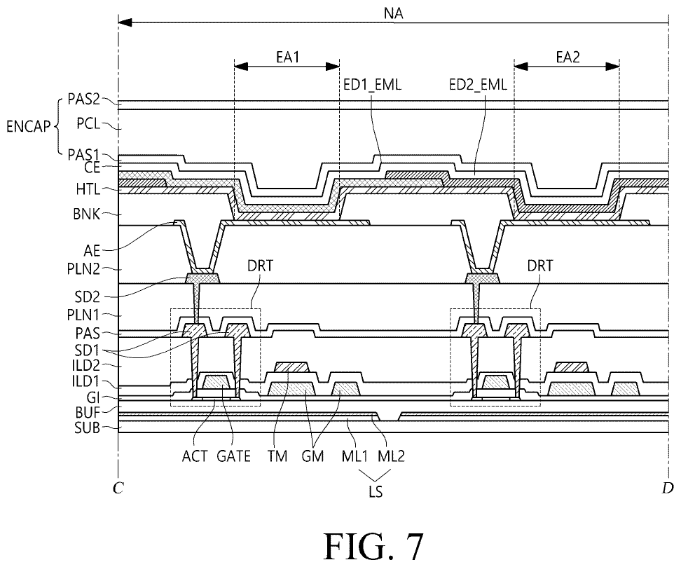

FIG. 6 is a first example cross-sectional view taken along line A-B of FIG. 5. FIG. 7 is an example cross-sectional view taken along line C-D of FIG. 5. In discussions that follow for the configuration of FIGS. 6 and 7, discussions for features and configurations equal, substantially equal, or similar to the features and configurations described with reference to FIGS. 1 to 5 are omitted or briefly described for convenience of description.

Referring to FIGS. 6 and 7, several patterns (ACT, SD1, and GATE), several insulating layers (BUF, GI, ILD1, ILD2, and PAS), and several metal patterns (TM, GM, ML1, and ML2) for forming at least one transistor such as a driving transistor DRT and the like can be disposed on a substrate SUB.

Referring to FIGS. 6 and 7, a first metal layer ML1 and a second metal layer ML2 can be disposed on the substrate SUB. For example, the first metal layer ML1 and the second metal layer ML2 can be light shielding layers LS for shielding light.

A buffer layer BUF can be disposed on the first metal layer ML1 and the second metal layer ML2. The buffer layer BUF can be in the form of a single layer or a multilayer. When the buffer layer BUF is in the form of a multilayer, the buffer layer BUF can include a multi-buffer layer and an active buffer layer.

An active layer ACT of a driving transistor DRT can be disposed on the buffer layer BUF.

A gate insulating layer GI can be disposed such that it covers the active layer ACT.

A gate electrode GATE (which can be referred to as a gate electrode layer GATE) of the driving transistor DRT can be disposed on the gate insulating layer GI.

In this configuration, at a location different from a location where the driving transistor DRT is disposed, at least one gate material layer GM can be disposed on the gate insulating layer GI, together with the gate electrode layer GATE of the driving transistor DRT.

A first interlayer insulating layer ILD1 can be disposed such that it covers the gate electrode layer GATE and the gate material layer GM.

A metal pattern TM can be disposed on the first interlayer insulating layer ILD1.

The metal pattern TM can be disposed at a location different from the location where the driving transistor DRT is disposed.

A second interlayer insulating layer ILD2 can be disposed such that it covers the metal pattern TM on the first interlayer insulating layer ILD1.

Two first source-drain electrode pattern layers SD1 can be disposed on the second interlayer insulating layer ILD2. One of the two first source-drain electrode pattern layers SD1 can be a source node of the driving transistor DRT, and the other thereof can be a drain node of the driving transistor DRT. The two first source-drain electrode pattern layers SD1 can be electrically connected to one side and another side facing each other in the active layer ACT respectively through contact holes of the second interlayer insulating layer ILD2, the first interlayer insulating layer ILD1, and the gate insulating layer GI.

Among regions of the active layer ACT, a region overlapping with the gate electrode layer GATE can be a channel region.

One of the two first source-drain electrode pattern layers SD1 can be connected to one side of the channel region in the active layer ACT, and the other of the two first source-drain electrode pattern layers SD1 can be connected to another opposing side of the channel region in the active layer ACT.

A passivation layer PAS can be disposed such that it covers the two first source-drain electrode pattern layers SD1.

At least one planarization layer PLN can be disposed on the passivation layer PAS. The at least one planarization layer PLN can include a first planarization layer PLN1 and a second planarization layer PLN2. The first planarization layer PLN1 can be disposed on the passivation layer PAS.

A second source-drain electrode pattern layer SD2 can be disposed on the first planarization layer PLN1.

The second source-drain electrode pattern layer SD2 can be connected to one of the two first source-drain electrode pattern layers SD1 (corresponding to the first node N1 of the driving transistor DRT in the subpixel SP of FIG. 4) through a contact hole of the first planarization layer PLN1.

The second planarization layer PLN2 can be disposed such that it covers the second source-drain electrode pattern layer SD2.

At least one light emitting element ED can be disposed on the second planarization layer PLN2.

In terms of the stack-up structure of the light emitting element ED, a first electrode AE can be disposed on the second planarization layer PLN2.

The first electrode AE can include a material having a relatively high work function.

The first electrode AE can include a transparent conductive oxide such as indium tin oxide (ITO), indium zinc oxide (IZO), zinc oxide (ZnO), Al-doped zinc oxide (AZO), indium oxide (In2O3), tin oxide (SnO2), or the like. However, implementations of the present disclosure are not limited thereto.

The first electrode AE can be electrically connected to the second source-drain electrode pattern layer SD2 through a contact hole of the second planarization layer PLN2.

A bank BNK can be disposed such that it covers a portion of the first electrode AE. A portion of the bank BNK corresponding to a light emitting area EA of a subpixel SP can be opened. The opened area of the bank BNK can be referred to as an open area or opening. The light emitting area EA can correspond to the open area of the bank BNK. For example, the portion of the first electrode AE can be exposed to the open area of the bank BNK.

An emission layer EL can be disposed on at least one side of the bank BNK and in the open area of the bank BNK. All or at least a portion of the emission layer EL can be located between adjacent banks BNK (or between portions of the bank BNK). The emission layer EL can contact the first electrode AE in the open area of the bank BNK.

A second electrode CE can be disposed on the emission layer EL.

The second electrode CE can include a metal, an alloy, an electrically conductive compound, or a mixture of two or more thereof, which have a relatively low work function.

For example, a transmissive or transparent electrode can be obtained by forming, in the form of a thin film, lithium (Li), magnesium (Mg), aluminum (Al), aluminum-lithium (Al—Li), calcium (Ca), magnesium-indium (Mg—In), magnesium-silver (Mg—Ag), or the like.

In some implementations, to obtain a top emitting device, various modifications can be made, such as forming a transparent electrode using ITO or IZO.

The emission layer EL can include an organic layer.

The emission layer EL can include a first emission layer ED1_EML disposed in a first subpixel SP1, a second emission layer ED2_EML disposed in a second subpixel SP2, and a third emission layer ED3_EML disposed in a third subpixel SP3. For example, the first emission layer ED1_EML can be a red emission layer emitting red light, the second emission layer ED2_EML can be a green emission layer emitting green light, and the third emission layer ED3_EML can be a blue emission layer emitting blue light. In this configuration, wavelengths of light emitted from these emission layers are longer in the order of the red emission layer, the green emission layer, and the blue emission layer.

A first common intermediate layer can be disposed between the emission layer EL and the first electrode AE. The first common intermediate layer can include a hole transport layer HTL or a hole injection layer HIL. For example, the hole transport layer HTL can be disposed between the emission layer EL and the first electrode AE.

The emission layer EL can be disposed such that adjacent emission layers EL partially overlap with each other on the bank BNK, or are spaced apart from each other thereon. For example, the first emission layer ED1_EML and the second emission layer ED2_EML can at least partially overlap with each other on the bank BNK. For example, respective at least a portion of the first emission layer ED1_EML and the second emission layer ED2_EML can overlap with each other on the bank BNK such that the at least a portion of the second emission layer ED2_EML is disposed on the at least a portion of the first emission layer ED1_EML.

The first emission layer ED1_EML, which is a red emission layer, can include a red host material and a red dopant material.

The red host material can include one of CBP (4,4′bis(carbozol-9-yl)biphenyl) and MCP (1,3-bis(carbazol-9-yl)benzene), or a mixture thereof, but implementations of the present disclosure are not limited thereto.

The red dopant material can be a material including one or more of an iridium (Ir) ligand complex including Ir(ppy)₃(tris(2-phenylpyridine)iridium(III)), Ir(ppy)₂(acac)(Bis(2-phenylpyridine)(acetylacetonato)iridium(III)), PIQIr(acac)(bis(1-phenylisoquinoline) acetylacetonate iridium), PQIr(acac)(bis(1-phenylquinoline) acetylacetonate iridium), PQIr(tris(1-phenylquinoline)iridium) Ir(piq)₃(tris(1-phenylisoquinoline)iridium), or Ir(piq)₂(acac)(bis(1-phenylisoquinoline)(acetylacetonate)iridium), PtOEP(octaethylporphyrinporphine platinum), PBD:Eu(DBM)3(Phen), or Perylene, but implementations of the present disclosure are not limited thereto.

The second emission layer ED2_EML, which is a green emission layer, can include a green host material and a green dopant material.

The green host material can include one of CBP (4,4′bis(carbozol-9-yl)biphenyl) and MCP (1,3-bis(carbazol-9-yl)benzene), or a mixture thereof, but implementations of the present disclosure are not limited thereto.

The green dopant material can be a material including one or more selected from the group of an iridium (Ir) ligand complex including Ir(ppy)3(tris(2-phenylpyridine)iridium(III)) or Ir(ppy)2(acac)(Bis(2-phenylpyridine)(acetylacetonato)iridium(III)), or Alq3(tris(8-hydroxyquinolino)aluminum), but implementations of the present disclosure are not limited thereto.

The third emission layer ED3_EML, which is a blue emission layer, can include a blue host material and a blue dopant material.

The blue host material can include one of Alq3 (tris(8-hydroxy-quinolino)aluminum), ADN (9,10-di(naphtha-2-yl) anthracene), and BSBF (2-(9,9-spirofluoren-2-yl)-9,9-spirofluorene), or a mixture of two or more thereof, but implementations of the present disclosure are not limited thereto.

The blue dopant material can be a material including one or more of a pyrene series substituted with an aryl amine compound, an iridium (Ir) ligand complex including (4,6-F2ppy)2Irpic, FIrPic (bis(3,5-difluoro-2-(2-pyridyl)phenyl-(2-carboxyprdidyl)iridium(III)), or Ir(ppy)3 (tris(2-phenylpyridine)iridium(III)), spiro-DPVBi, spiro-6P, spiro-BDAVBi (2,7-bis[4-(diphenylamino)styryl]-9,9′-spirofluorene), distilbenzene (DSB), distriarylene (DSA), a PFO polymer, and a PPV polymer, but implementations of the present disclosure are not limited thereto.

As discussed above, the first electrode AE, the emission layer EL, and the second electrode CE included in the light emitting element ED have been described.

Hereinafter, the stack-up structure of transmissive areas TA in the optical area OA is described in detail.

Referring to FIGS. 6 and 7, in some implementations, the second electrode CE can be disposed in the normal area NA and a non-transmissive area included in the optical area OA and not disposed in a transmissive area TA in the optical area OA. For example, the transmissive area TA in the optical area OA can correspond to an open area of the second electrode CE.

Further, in some implementations, a light shielding layer LS including at least one of the first metal layer ML1 and the second metal layer ML2 can be disposed in the normal area NA and the non-transmissive area included in the optical area OA and not disposed in the transmissive area TA of the optical area OA.

The substrate SUB and several insulating layers (BUF, GI, ILD1, ILD2, PAS, PLN1, PLN2, BNK, and ENCAP) disposed in the normal area NA and the non-transmissive area included in the optical area OA can also be disposed in the transmissive area TA of the optical area OA.

In this configuration, a material layer having electrical properties (e.g., a metal material layer, a semiconductor layer, and the like) other than one or more insulating materials included in the normal area NA and the non-transmissive area included in the optical area OA are not be disposed in the transmissive area TA of the optical area OA.

For example, referring to FIGS. 6 and 7, in some implementations, the metal material layers (ML1, ML2, GATE, GM, TM, SD1, and SD2) and the semiconductor layer ACT related to at least one transistor are not disposed in the transmissive area TA. Further, in some implementations, the first electrode AE and the second electrode CE included in the light emitting element ED are not disposed in the transmissive area TA. In some implementations, the emission layer EL can optionally be disposed in the transmissive area TA.

According to the foregoing configurations, since a material layer (e.g., a metal material layer, a semiconductor layer, and the like) having electrical properties is not disposed in the transmissive area TA in the optical area OA, the transmittance of the transmissive area TA in the optical area OA can be increased.

Accordingly, the optical electronic device 11 can receive light transmitted through the transmissive area TA and perform a corresponding function (e.g., detecting the approach of an object or a human body, detecting external illuminance, and the like).

The stack-up structure of the transmissive area TA of the optical area OA has been described above.

Hereinafter, discussion for an infrared emission part NIRL are provided with reference to FIGS. 6 and 7. Herein, the infrared emission part NIRL can also be referred to as an infrared emission element NIRL, an infrared emission structure NIRL, an infrared emission layer NIRL, or an infrared emission stack NIRL.

Referring to FIGS. 6 and 7, FIG. 6 illustrates that an infrared emission part NIRL overlapping with the bank BNK is disposed in the optical area OA. In contrast, FIG. 7 illustrates that an infrared emission part NIRL is not disposed in the normal area NA.

Referring to FIG. 6, an infrared emission part NIRL covering at least a portion of the bank BNK can be disposed on the bank BNK. In this configuration, the optical electronic device 11 overlapped with at least a portion of the infrared emission part NIRL can be disposed under the bank BNK. The optical electronic device 11 can be an optical sensor.

The optical electronic device 11 can be located over or under the substrate SUB. Hereinafter, discussions are provided based on an example where the optical electronic device 11 is located under the substrate SUB.

The optical electronic device 11 can be an illuminance sensor, which can also be referred to as an ambient light sensor. The illuminance sensor can measure an amount of ambient light. The illuminance sensor can be a sensor capable of measuring the amount of light in the visible light spectrum without measuring the amount of light in the infrared (e.g., near infrared) spectrum.

Referring to FIG. 6, the infrared emission part NIRL can be located between the first subpixel SP1 and the second subpixel SP2. However, the location of the infrared emission part NIRL is not limited thereto. For example, the infrared emission part NIRL can be located between the second subpixel SP2 and the third subpixel SP3, or between the first subpixel SP1 and the third subpixel SP3. For example, the first subpixel SP1 can be a red subpixel emitting red light, the second subpixel SP2 can be a green subpixel emitting green light, and the third subpixel SP3 can be a blue subpixel emitting blue light.

It should be noted here that in a structure where a common intermediate layer is applied, a phenomenon can be observed where current flows laterally through the common intermediate layer disposed continuously in a lateral direction as the common intermediate layer is commonly disposed in two or more subpixels SP. In particular, a common intermediate layer with high conductivity among common intermediate layers can cause the lateral leakage current. In this case, a situation can occur in which lateral leakage current is transferred to a subpixel having a low threshold voltage through the common intermediate layer depending on a difference of threshold voltages between subpixels.

For example, when the first subpixel SP1 is driven, a phenomenon in which the second emission layer ED2_EML of the second subpixel SP2 emits downwardly can occur due to lateral leakage current LLC flowing along a hole transport layer HTL included in a first common intermediate layer in the first light emitting element ED1. In this case, the downward emission (which can be referred to as bottom emission) can be a phenomenon caused by a structure where the first emission layer ED1_EML and the second emission layer ED2_EML partially overlap with each other on the hole transport layer HTL. Accordingly, a malfunction of the optical electronic device 11 can occur due to light emitted from the second emission layer ED2_EML due to the lateral leakage current LLC.

Further, since each light emitting element disposed in subpixels SP has respective rising and falling times different from each other when driven, there can be present a difference in delay characteristics between light emitting elements during rising and falling. A delay time, which is one of the delay characteristics, can be a falling time. Further, the delay time can be a time that is the sum of the rising time and the falling time. In particular, when the falling time when a light emitting element is turned off is long, a problem can occur in which some subpixels continue to emit light even when the light emitting element is turned off, resulting in an increased amount of light. Accordingly, when a light emitting element required to be turned off continues to emit light due to a difference in delay characteristics between subpixels, a malfunction of the optical electronic device 11 can occur due to unintended light.

To address this issue, as illustrated in FIG. 6, the infrared emission part NIRL can be disposed such that it at least partially overlaps with the bank BNK. The first emission layer ED1_EML of the first subpixel SP1 and the second emission layer ED2_EML of the second subpixel SP2 can at least partially overlap with each other on the infrared emission part NIRL. For example, at least a portion of the second emission layer ED2_EML can be disposed on at least a portion of the first emission layer ED1_EML, but implementations of the present disclosure are not limited thereto.

The first subpixel SP1 can have a first threshold voltage, and the second subpixel SP2 can have a second threshold voltage. For example, the second threshold voltage can be less than the first threshold voltage. Further, the infrared emission part NIRL can have a third threshold voltage. The third threshold voltage can be less than the first threshold voltage and the second threshold voltage, but implementations of the present disclosure are not limited thereto. When the third subpixel SP3 has a fourth threshold voltage, the third threshold voltage can be less than the first threshold voltage, the second threshold voltage, and the fourth threshold voltage.

When the third threshold voltage is less than the first threshold voltage and the second threshold voltage, the infrared emission part NIRL can emit light due to lateral leakage current LLC flowing along the hole transport layer HTL included in the first common intermediate layer in the first light emitting element ED1 of the first subpixel SP1. For example, since the third threshold voltage is lower than the second threshold voltage, the infrared emission part NIRL (and not the second emission layer ED2_EML of the second subpixel SP2) can emit light.

The infrared emission part NIRL can emit light in the infrared spectrum, particularly near-infrared spectrum with a wavelength of 700 to 1,100 nm. Therefore, even when the infrared emission part NIRL emits light due to the lateral leakage current LLC, the malfunction of the optical electronic device 11, which can be disposed to be partially overlapped with the infrared emission part NIRL, can be prevented or at least reduced.

The first subpixel SP1 can have a first delay time, and the second subpixel SP2 can have a second delay time. For example, the second delay time can be greater than the first delay time.

The first delay time can be a first falling time of the first subpixel SP1, and the second delay time can be a second falling time of the second subpixel SP2. Further, the first delay time can be a time that is the sum of the first rising time and the first falling time of the first subpixel SP1, and the second delay time can be a time that is the sum of the second rising time and the second falling time of the second subpixel SP2.

The infrared emission part NIRL can emit light by the lateral leakage current LLC flowing along the hole transport layer HTL included in the first common intermediate layer in the first light emitting element ED1 of the first subpixel SP1. In this case, since the infrared emission part NIRL emits light by the lateral leakage current LLC, the amount of light by the emission of the second subpixel SP2 can be reduced, and thereby, the malfunction of the optical electronic device 11 can be prevented or at least reduced.

Referring to FIG. 6, the infrared emission part NIRL can be disposed between the bank BNK and the first common intermediate layer. In this configuration, the infrared emission part NIRL, the first emission layer ED1_EML, and the second emission layer ED2_EML can at least partially overlap with each other. For example, the infrared emission part NIRL, the first common intermediate layer, the first emission layer ED1_EML, and the second emission layer ED2_EML can be disposed to overlap with each other on the bank BNK.

The bank BNK can include at least one side surface and an upper surface. The infrared emission part NIRL can be disposed on the at least one side surface and the upper surface of the bank BNK. In this configuration, the infrared emission part NIRL can be disposed to be spaced apart from the first electrode AE disposed under the bank BNK.

The infrared emission part NIRL can emit light in the near-infrared spectrum with a wavelength of 700 to 1,100 nm. The infrared emission part NIRL can absorb light in the visible light spectrum and emit light in the near infrared spectrum. The infrared emission part NIRL can absorb light with a wavelength of 495 to 570 nm and emit light in the near infrared spectrum. For example, the infrared emission part NIRL can absorb light in the visible light spectrum with a wavelength of 495 to 570 nm and emit light in the near infrared spectrum with a wavelength of 700 to 1,100 nm.

The infrared emission part NIRL can include an infrared emitting material capable of emitting light in the near infrared spectrum with a wavelength of 700 to 1,100 nm. The infrared emission part NIRL can include an infrared emitting material capable of absorbing light in the visible light spectrum and emitting light in the near-infrared spectrum. The infrared emission part NIRL can include an infrared emitting material capable of absorbing light having a wavelength of 495 to 570 nm and emitting light in the near-infrared spectrum. For example, the infrared emission part NIRL can include an infrared emitting material capable of absorbing light in the visible light spectrum with a wavelength of 495 to 570 nm and emiting light in the near infrared spectrum with a wavelength of 700 to 1,100 nm.

The infrared emitting material can be an organic material or a metal-organic material including a metal.

For example, the infrared emitting material including the organic material can be an organic material as follows.

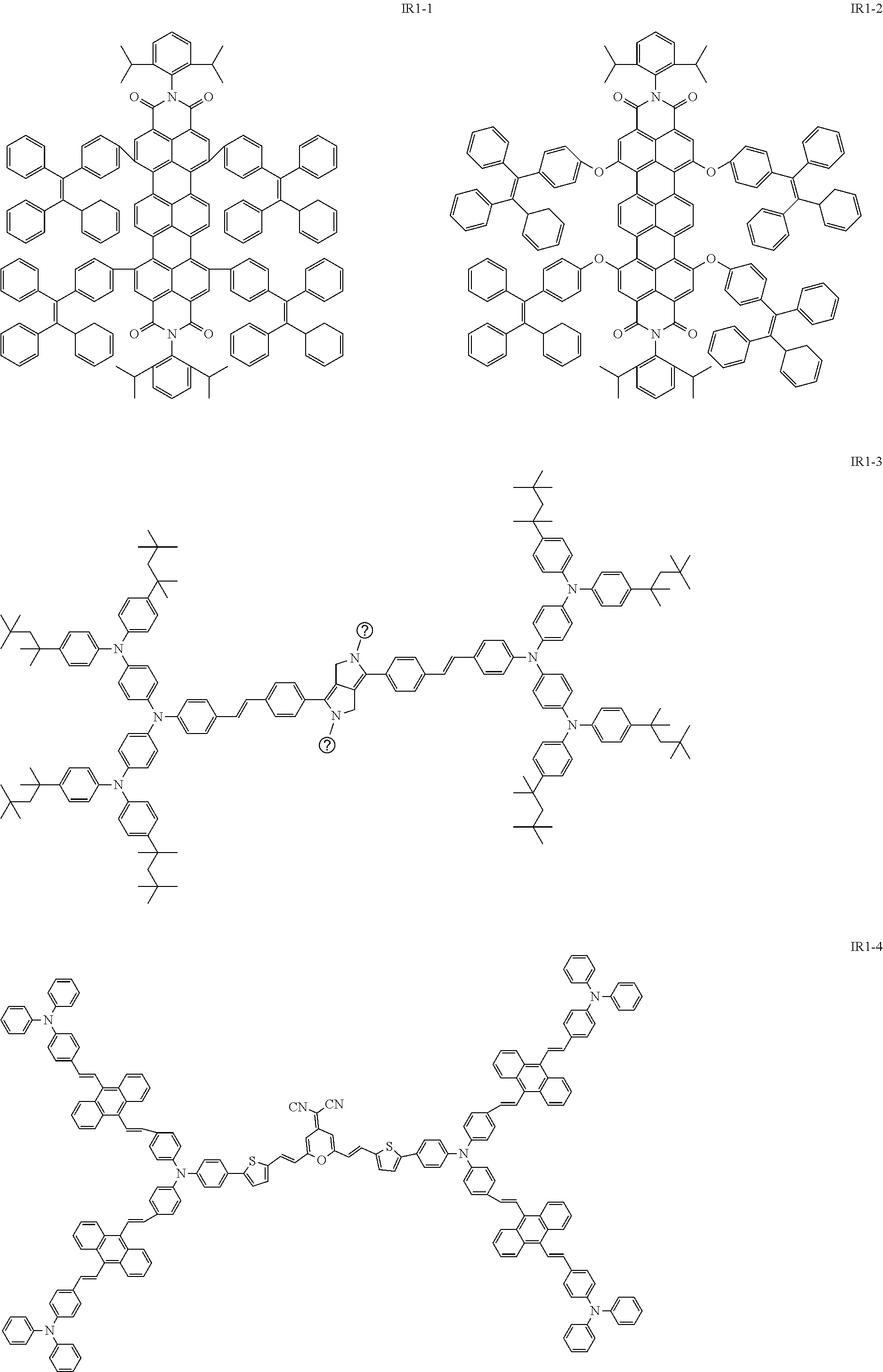

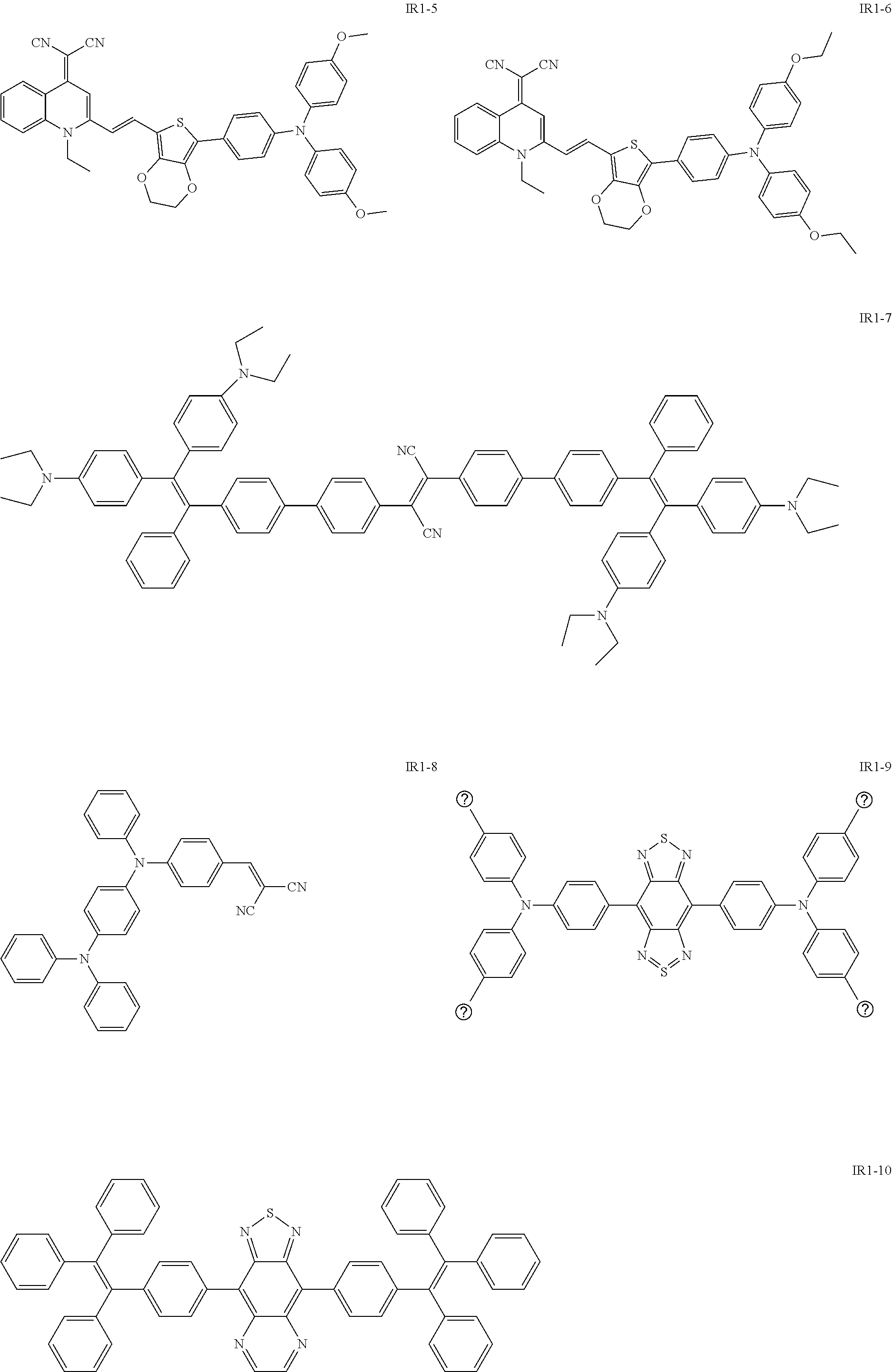

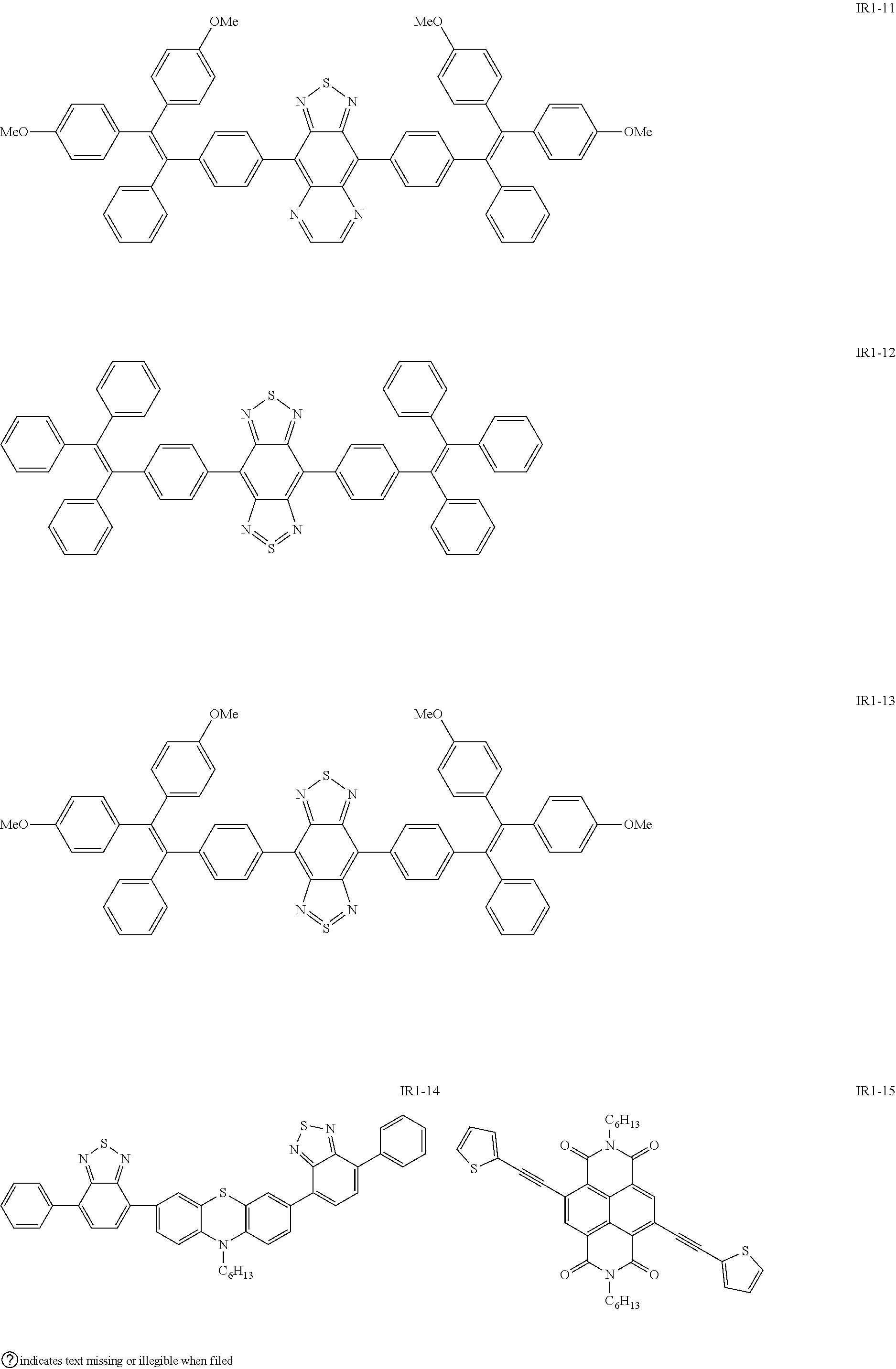

The metal included in the metal-organic material can be platinum (Pt), iridium (Ir), ruthenium (Ru), or the like. Further, the metal included in the metal-organic material can be erbium (Er), lanthanum (Nd), ytterbium (Yb), holium (Ho), tholium (Tm), or the like. For example, the infrared emitting material, which is the metal-organic material including a metal can be a metal-organic material as follows.

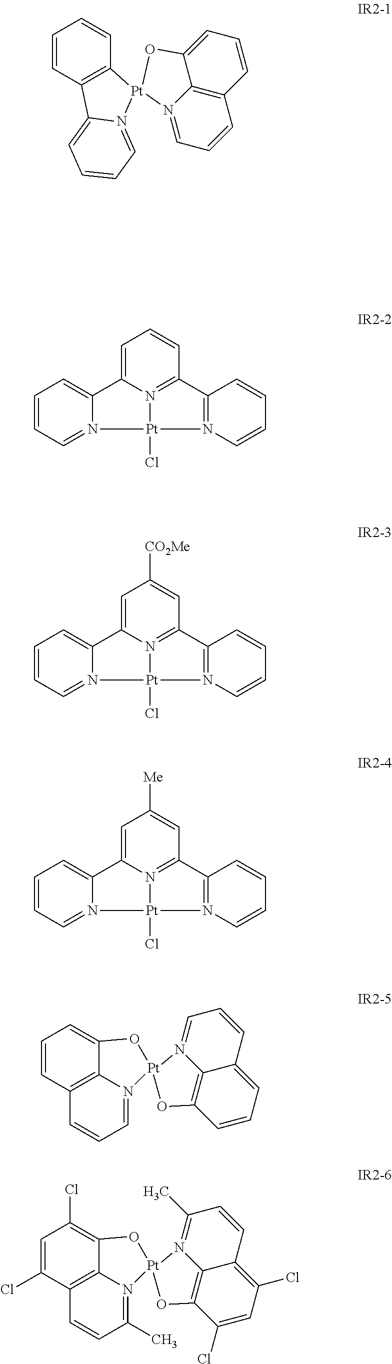

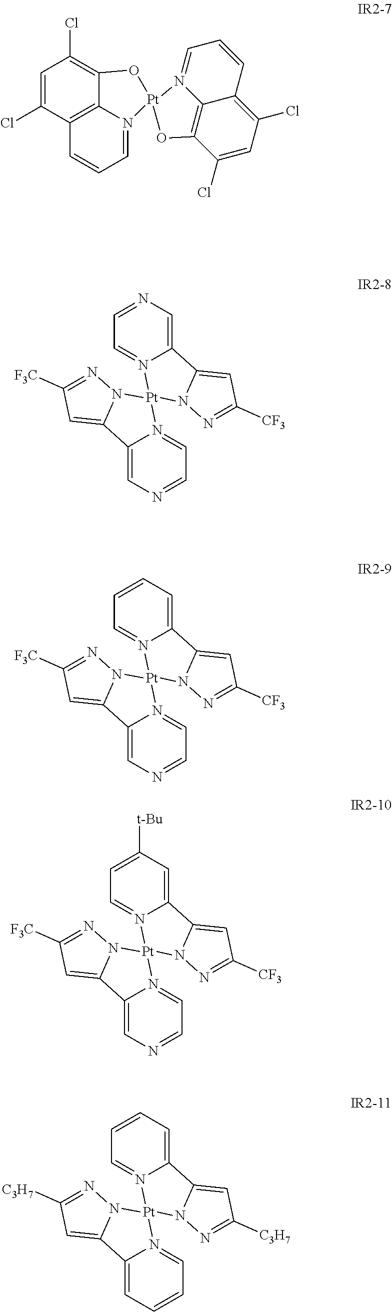

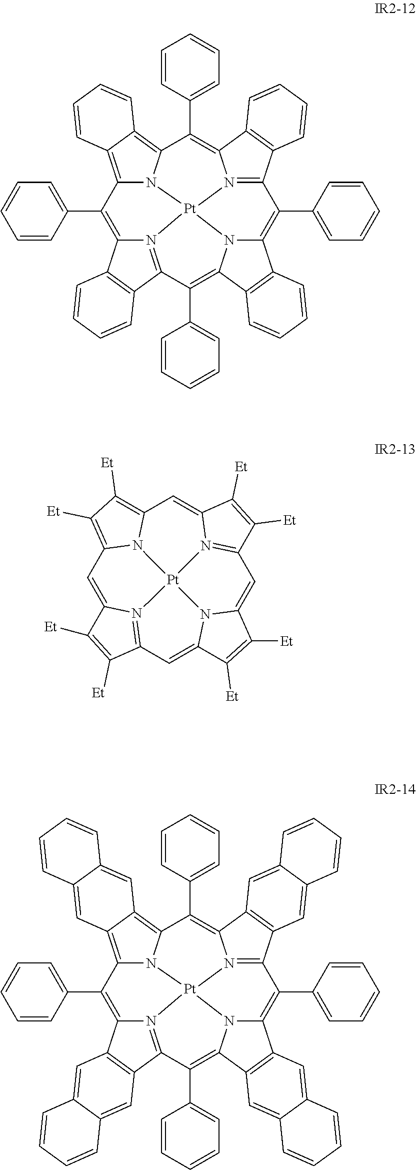

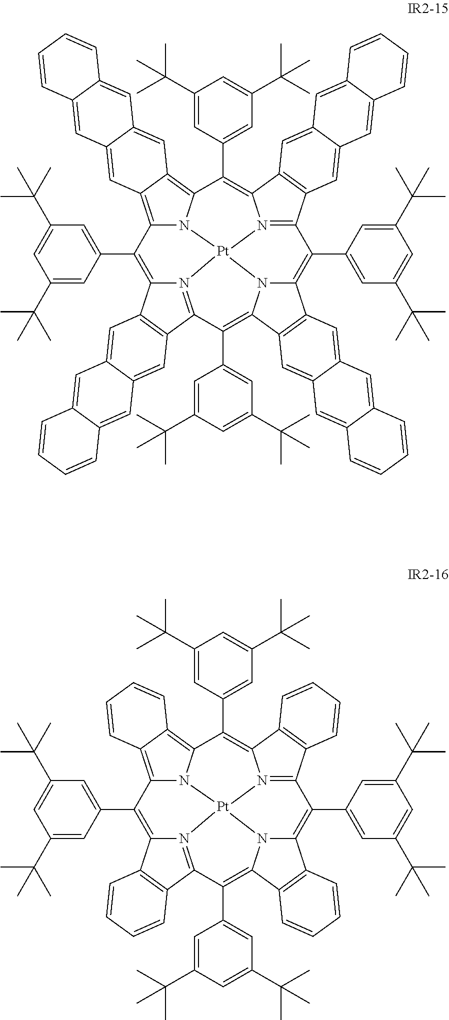

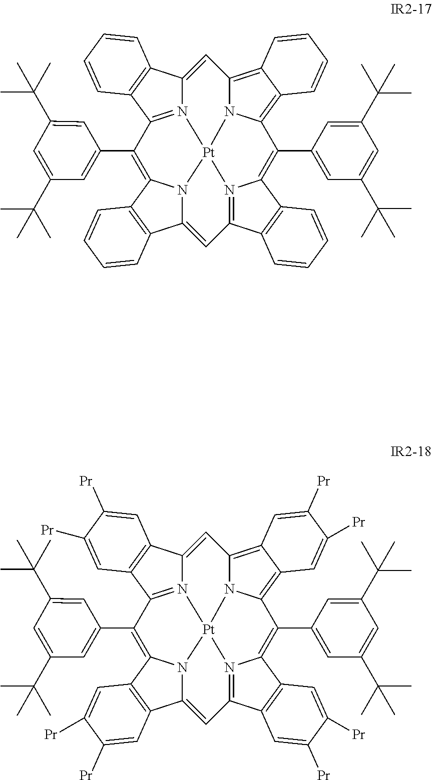

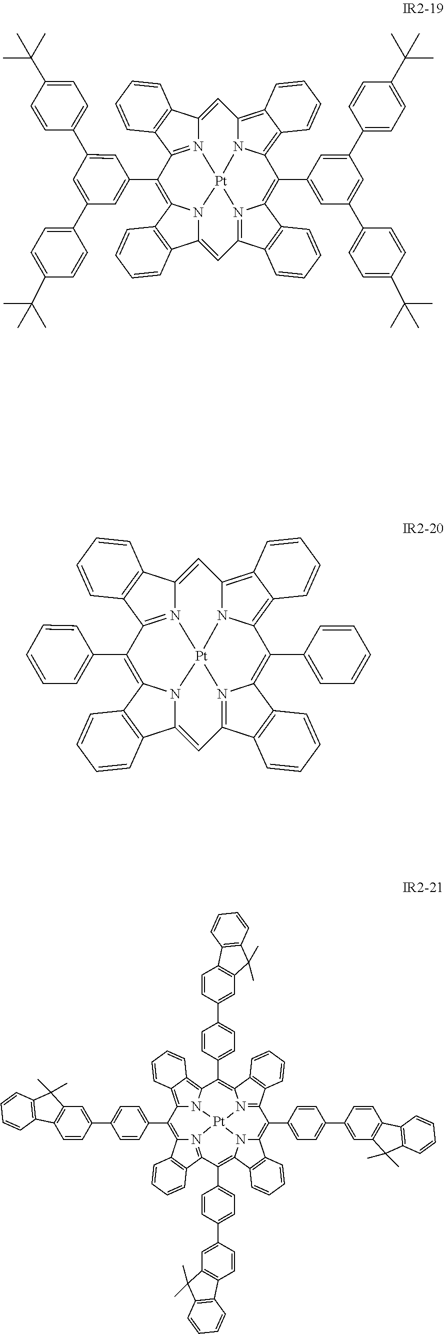

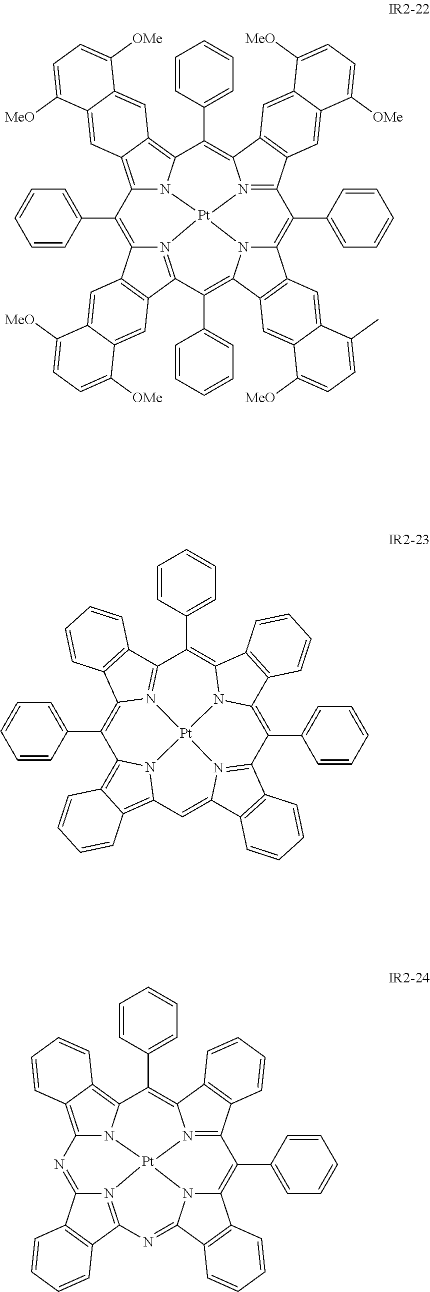

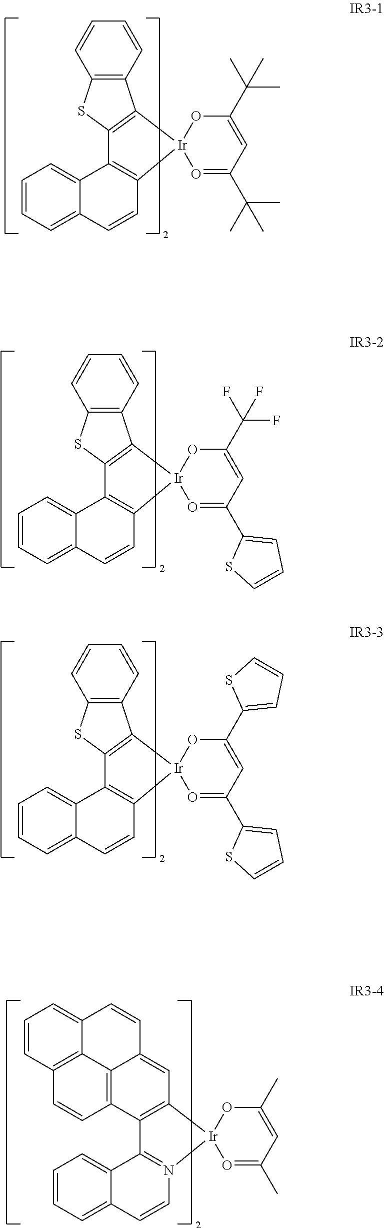

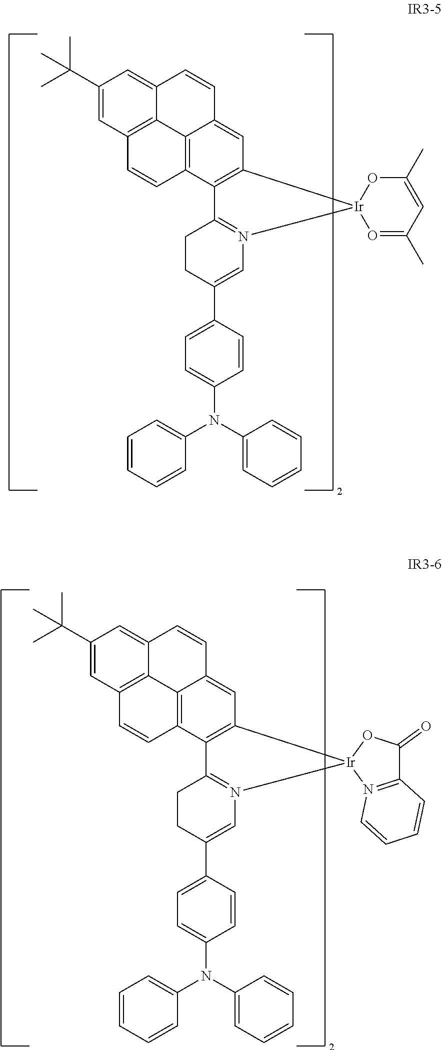

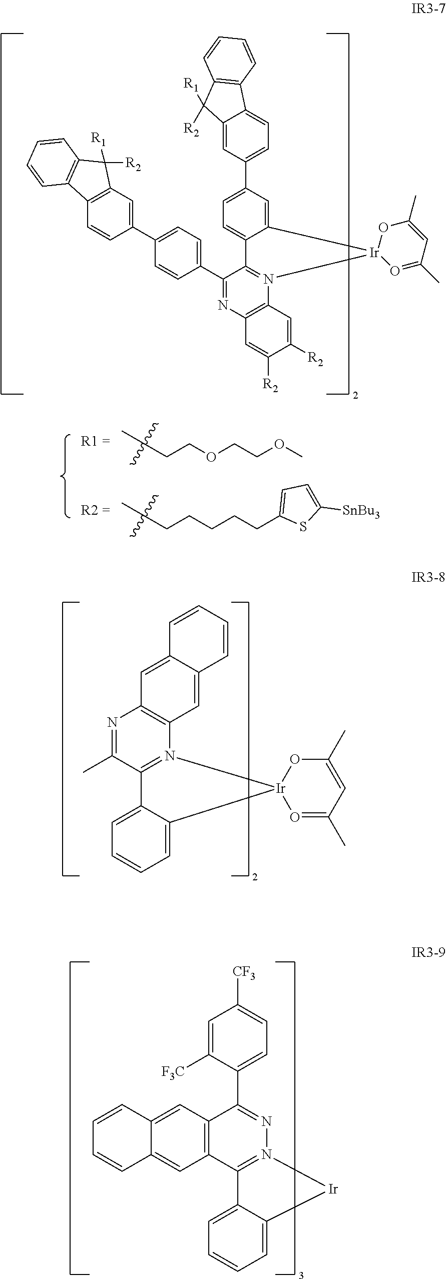

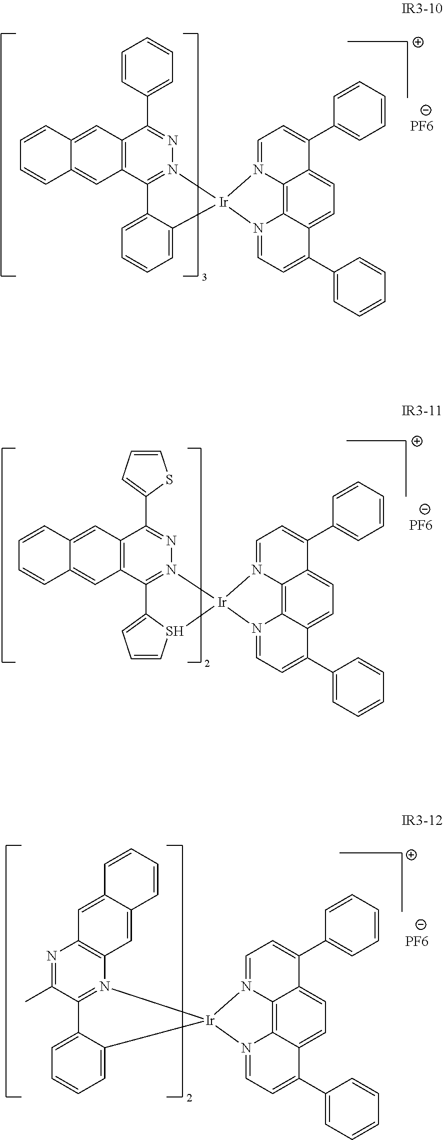

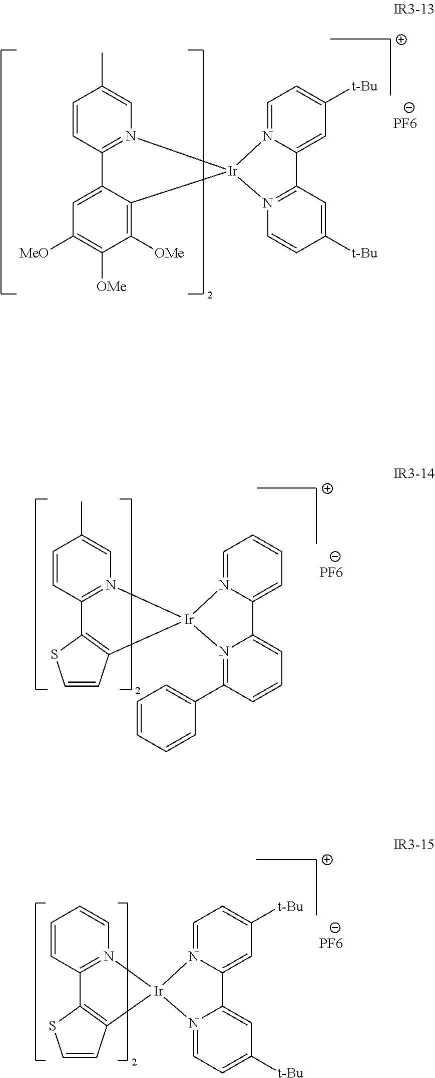

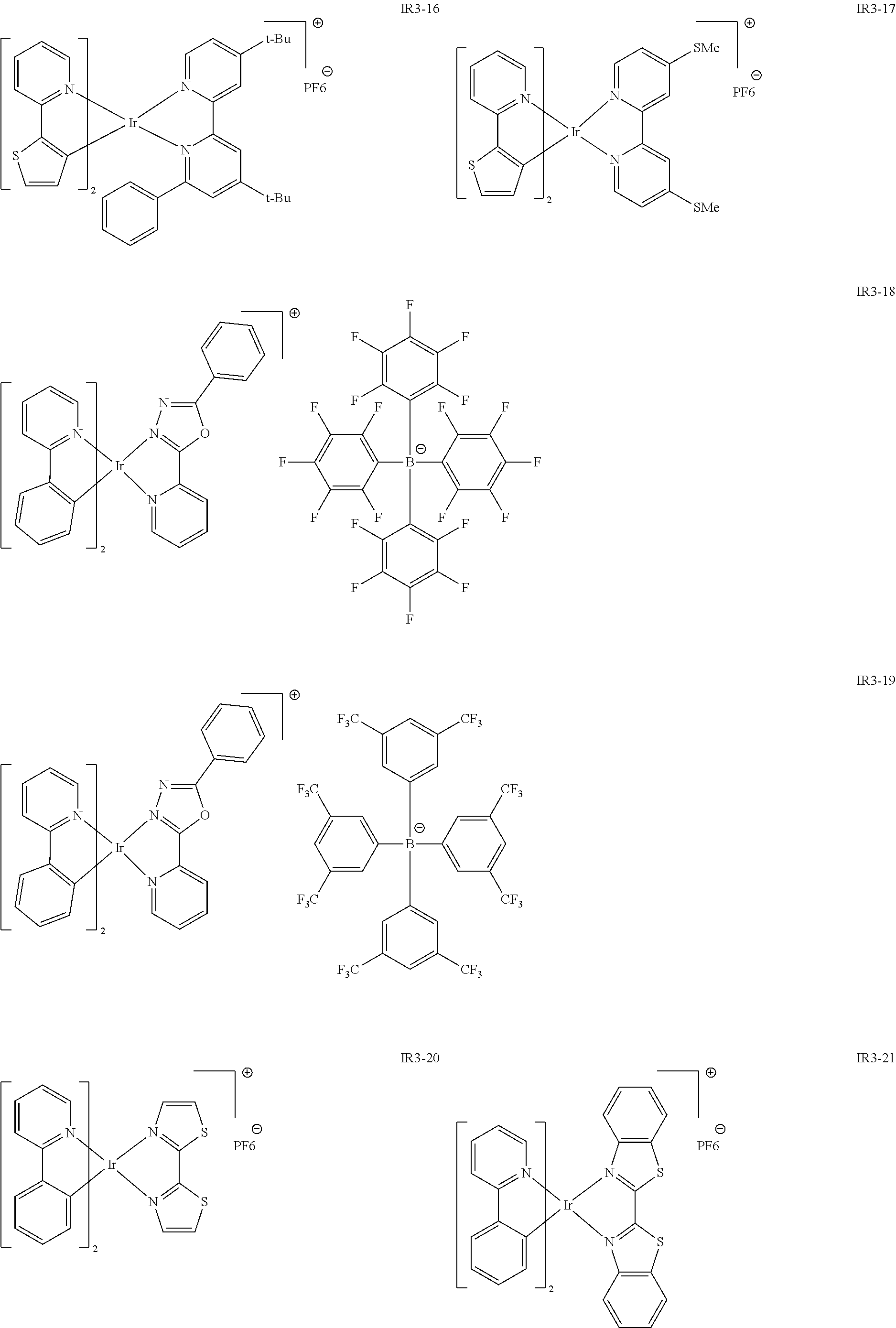

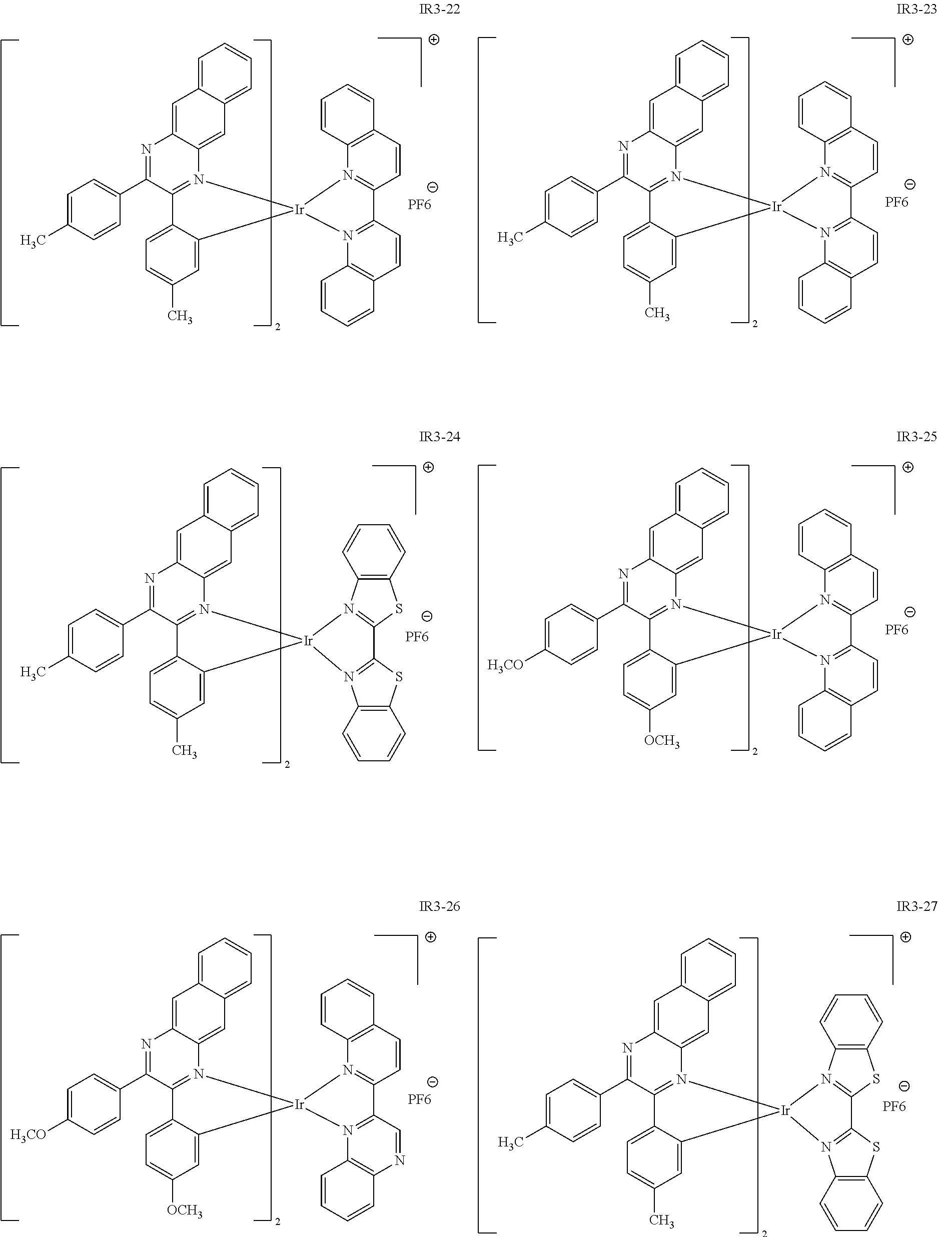

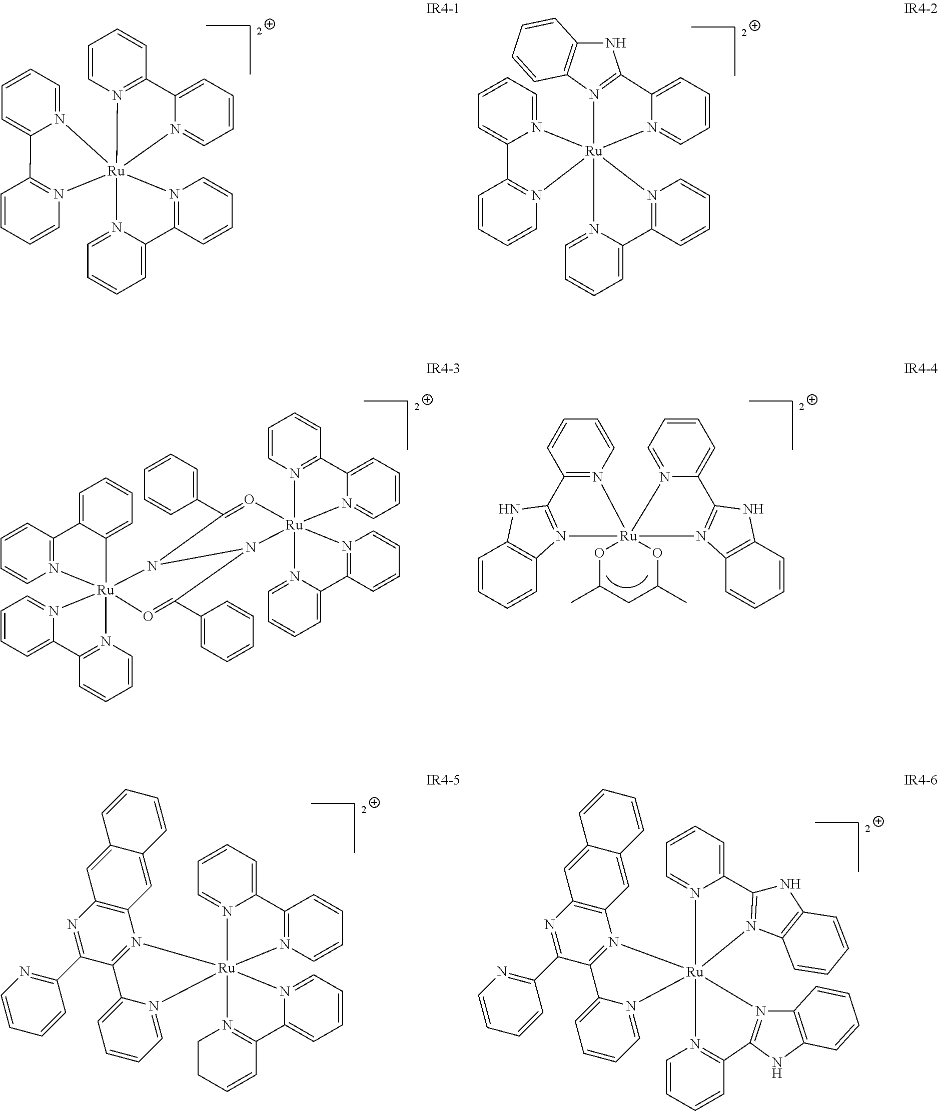

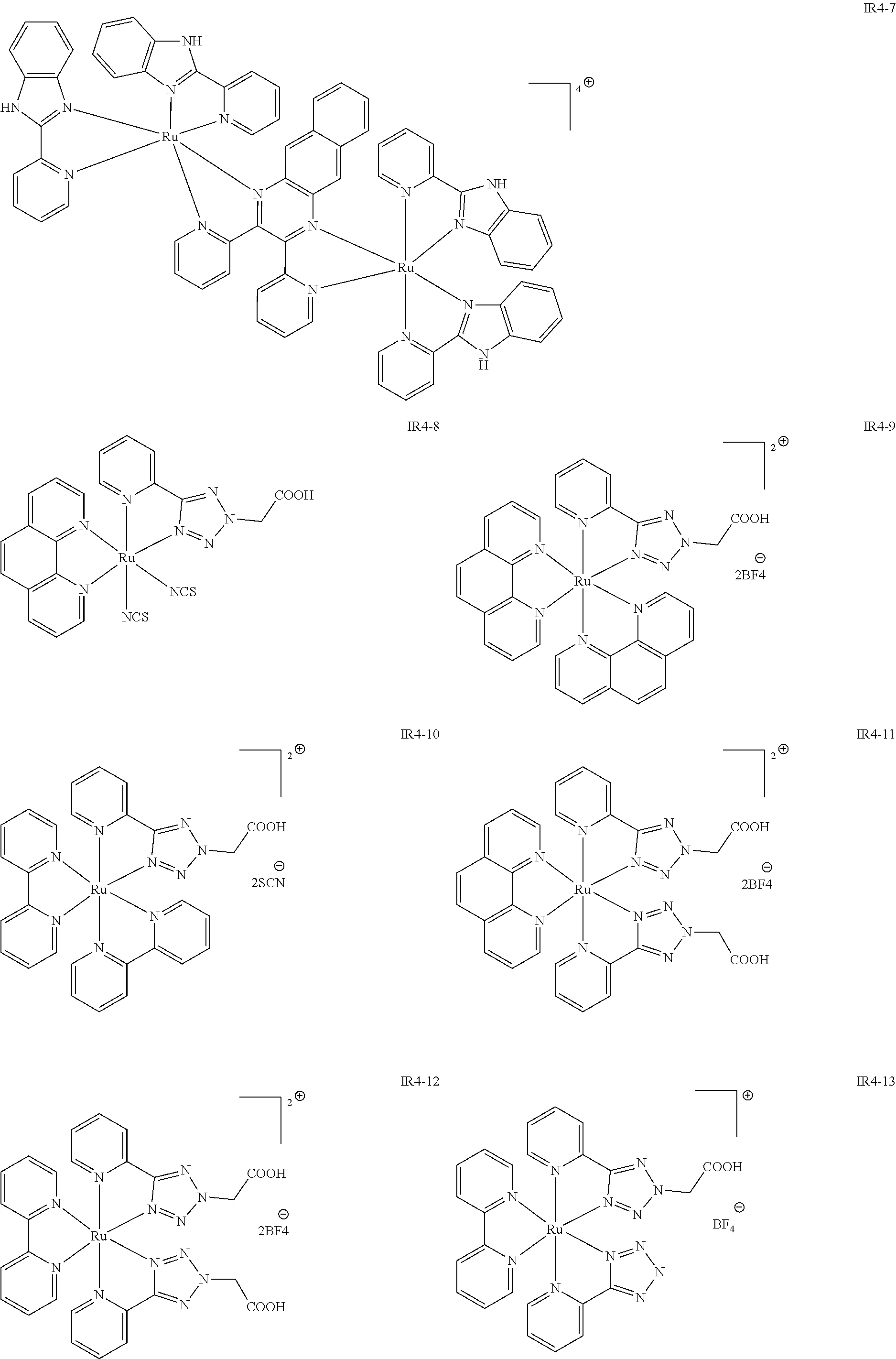

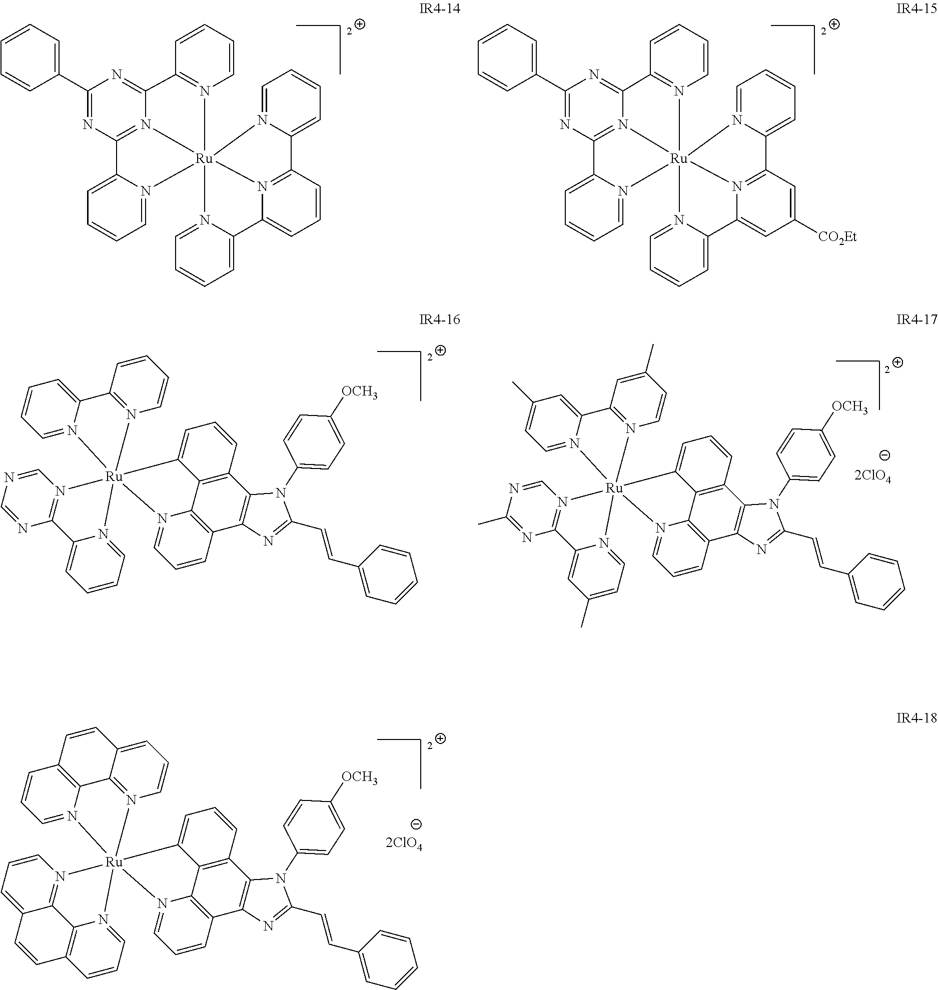

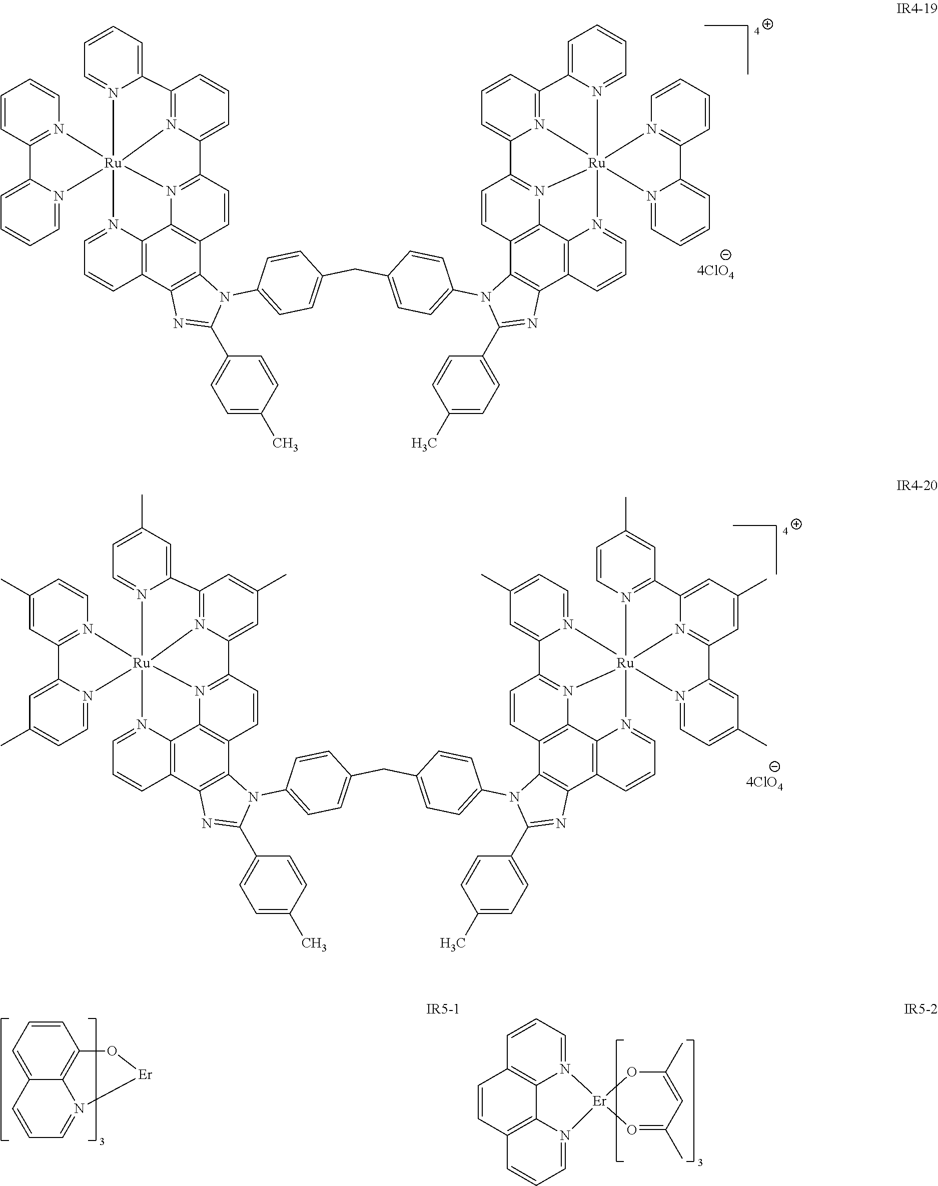

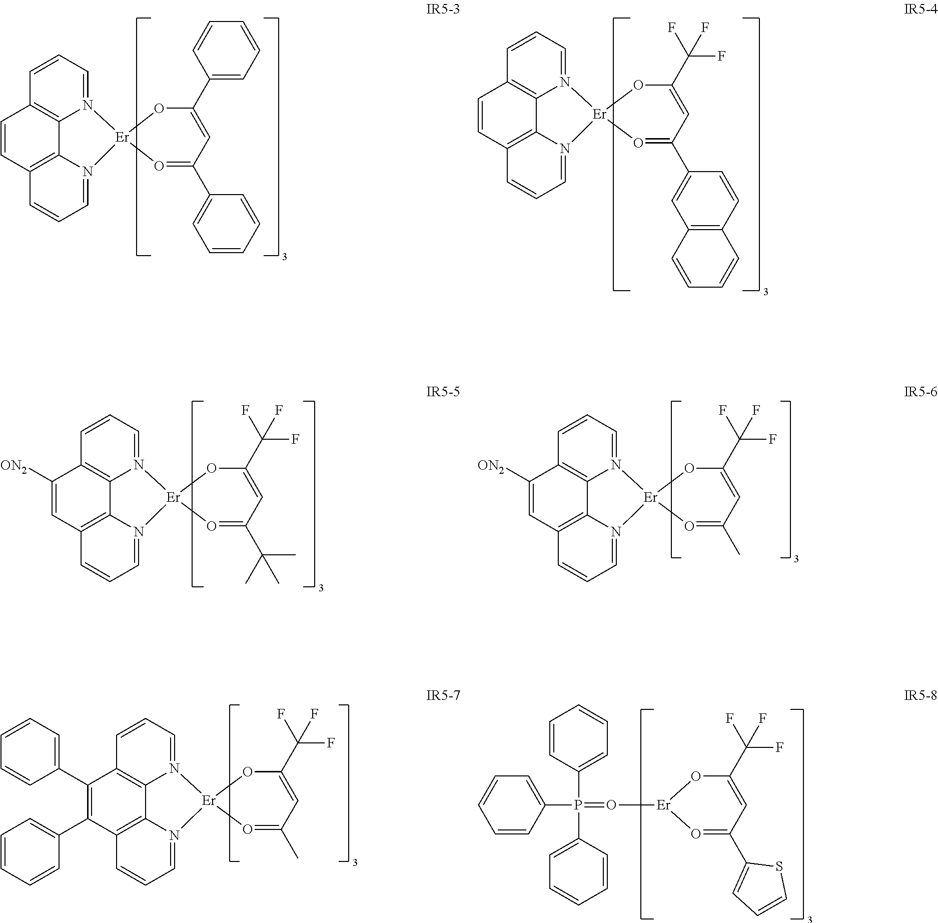

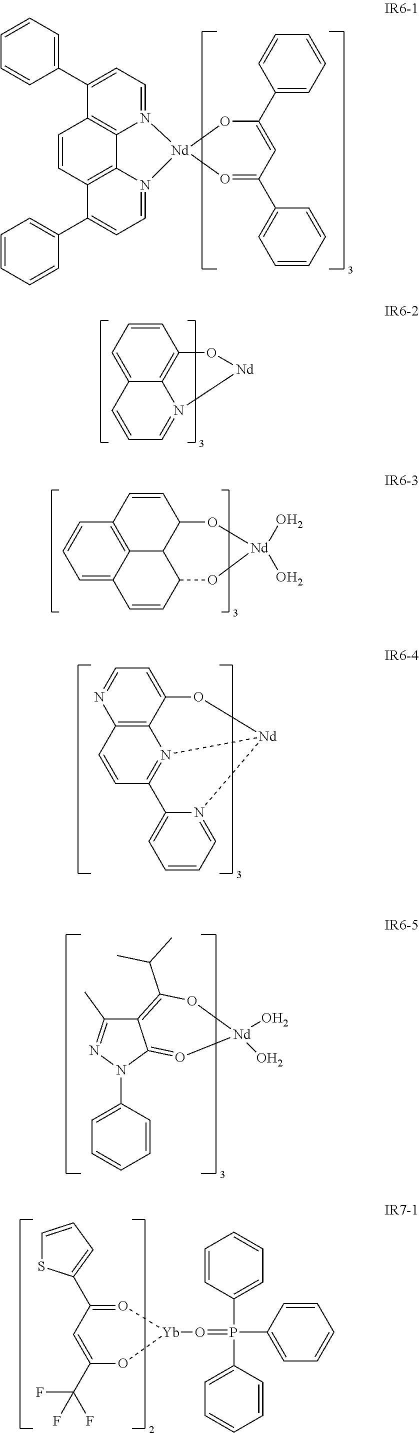

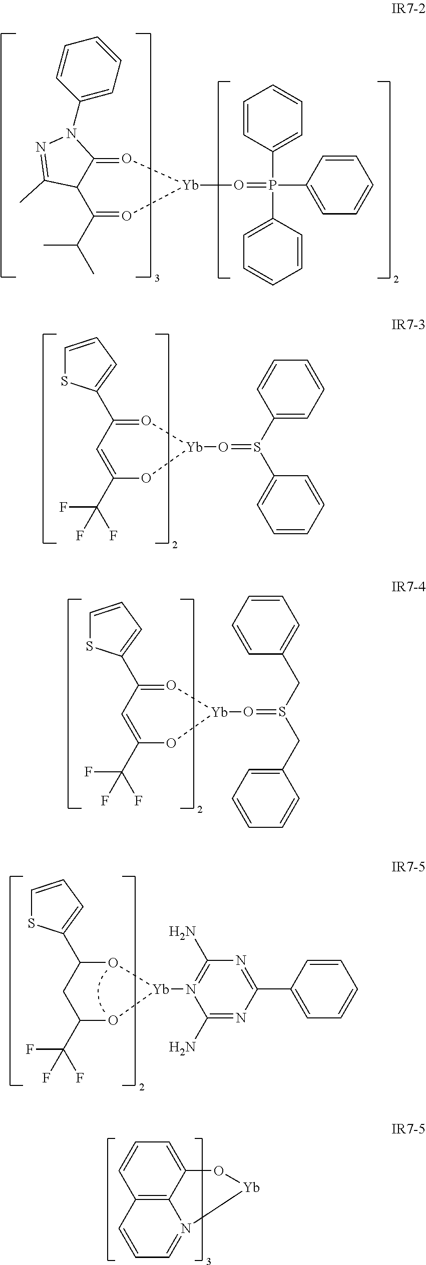

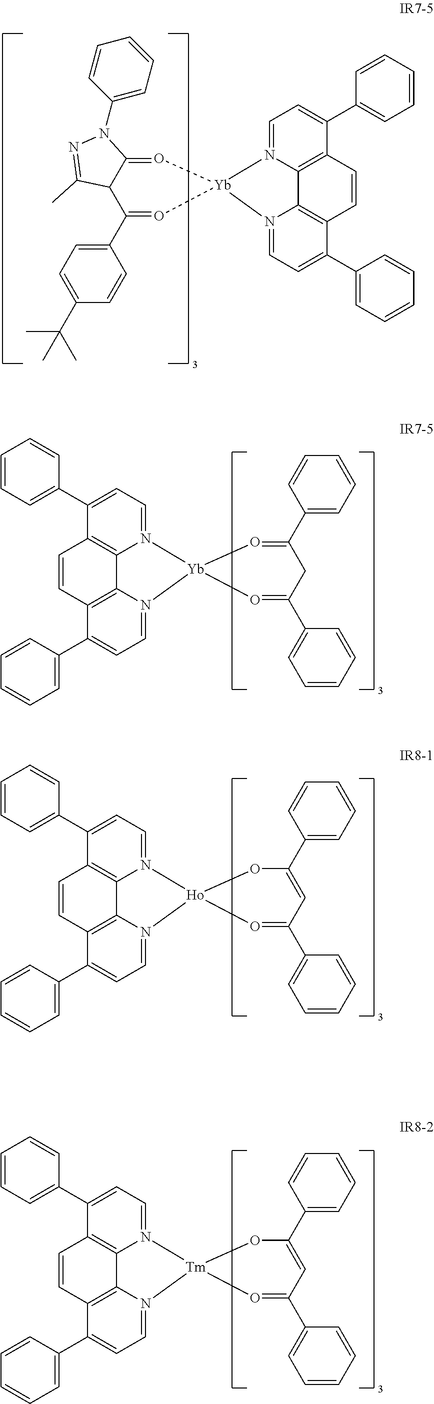

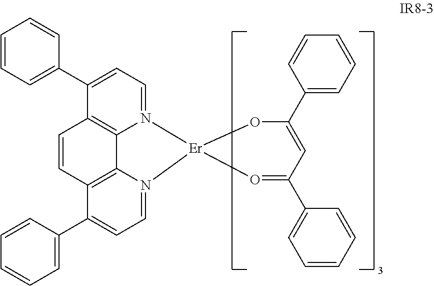

Referring to FIG. 6, when the first subpixel SP1 is driven, as the infrared emission part NIRL emits light due to the lateral leakage current LLC flowing along the first common intermediate layer including the hole transport layer HTL in the first light emitting element ED1, the display device 100 can provide an advantage of preventing or at least reducing the malfunction of the optical electronic device 11, which can be disposed to be partially overlapped with the infrared emission part NIRL.

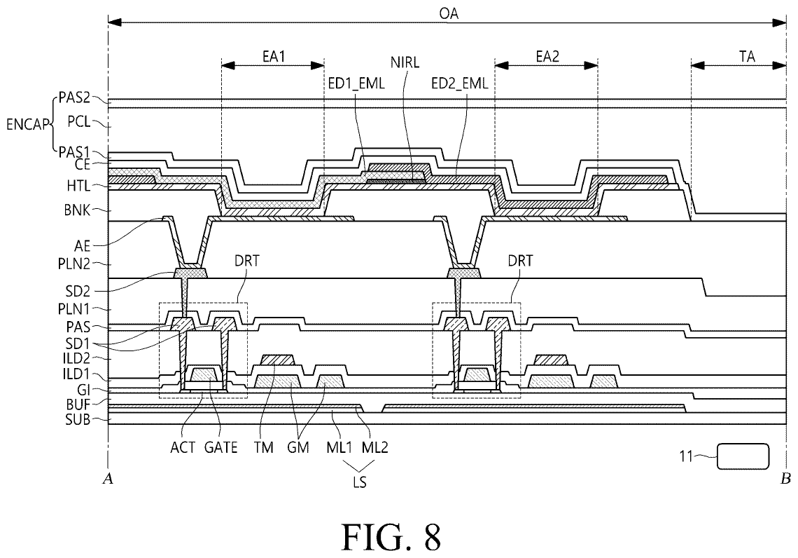

FIGS. 8 to 10 are example cross-sectional views taken along line A-B of FIG. 5. In discussions that follow for the configuration of FIGS. 8 to 10, discussions for features and configurations equal, substantially equal, or similar to the features and configurations described with reference to FIGS. 1 to 7 are omitted or briefly described for convenience of description.

Referring to FIG. 8, in some implementations, an infrared emission part NIRL can be disposed to overlap with at least a portion with the bank BNK. The first emission layer ED1_EML of the first subpixel SP1 and the second emission layer ED2_EML of the second subpixel SP2 can at least partially overlap with each other on the infrared emission part NIRL. For example, at least a portion of the second emission layer ED2_EML can be disposed on at least a portion of the first emission layer ED1_EML, but implementations of the present disclosure are not limited thereto.

Referring to FIG. 8, the infrared emission part NIRL can be disposed between the first common intermediate layer and the emission layer EML. In this configuration, the infrared emission part NIRL, the first emission layer ED1_EML, and the second emission layer ED2_EML can at least partially overlap with each other. For example, the first common intermediate layer, the infrared emission part NIRL, the first emission layer ED1_EML, and the second emission layer ED2_EML can be disposed to overlap with each other on the bank BNK.

A width of the infrared emission part NIRL can be greater than or equal to a width of an area where the first emission layer ED1_EML and the second emission layer ED2_EML overlap with each other. When the width of the infrared emission part NIRL is greater than or equal to the width of the area where the first emission layer ED1_EML and the second emission layer ED2_EML overlap with each other, the emission of the second subpixel SP2 can be prevented or at least reduced due to lateral leakage current LLC.

Referring to FIG. 8, when the first subpixel SP1 is driven, as the infrared emission part NIRL emits light due to the lateral leakage current LLC flowing along the first common intermediate layer including the hole transport layer HTL in the first light emitting element ED1, the display device 100 can provide an advantage of preventing or at least reducing the malfunction of the optical electronic device 11, which can be disposed to be partially overlapped with the infrared emission part NIRL.

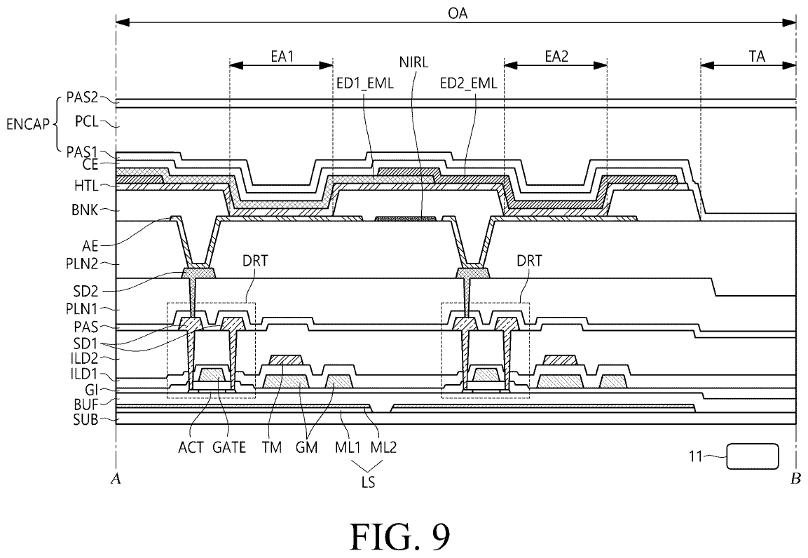

Referring to FIG. 9, in some implementations, an infrared emission part NIRL can be disposed to at least partially overlap with the bank BNK. The first emission layer ED1_EML of the first subpixel SP1 and the second emission layer ED2_EML of the second subpixel SP2 can at least partially overlap with each other on the infrared emission part NIRL. For example, at least a portion of the second emission layer ED2_EML can be disposed on at least a portion of the first emission layer ED1_EML, but implementations of the present disclosure are not limited thereto.

Referring to FIG. 9, the infrared emission part NIRL can be disposed between the substrate SUB and the bank BNK. For example, the infrared emission part NIRL can be disposed between the second planarization layer PLN2 and the bank BNK. In this configuration, the infrared emission part NIRL, the first emission layer ED1_EML, and the second emission layer ED2_EML can at least partially overlap with each other. For example, the infrared emission part NIRL, the bank BNK, the first common intermediate layer, the first emission layer ED1_EML, and the second emission layer ED2_EML can be disposed to overlap with each other on the second planarization layer PLN2.

Referring to FIG. 9, when the second emission layer ED2_EML in an area where the first emission layer ED1_EML and the second emission layer ED2_EML overlap with each other emits downwardly due to lateral leakage current LLC, the infrared emission part NIRL disposed to be overlapped with the second emission layer ED2_EML can emit near-infrared light. For example, light in the visible light spectrum emitted from the second emission layer ED2_EML can be absorbed and converted into light in the near-infrared spectrum by the infrared emission part NIRL, and thereby, the near-infrared light can be emitted.

Further, even when the light emitting element required to be turned off continuously emits light due to a difference in delay characteristics between the subpixels SP, this light can be absorbed and converted into light in the near-infrared spectrum by the infrared emission part NIR, and thereby, the near-infrared light can be emitted.

A width of the infrared emission part NIRL can be greater than or equal to a width of an area where the first emission layer ED1_EML and the second emission layer ED2_EML overlap with each other. When the width of the infrared emission part NIRL is greater than or equal to the width of the area where the first emission layer ED1_EML and the second emission layer ED2_EML overlap with each other, unintended light in the visible light spectrum absorbed by the infrared emission part NIRL can be efficiently converted into light in the near infrared spectrum.

The infrared emission part NIRL can be disposed in the same layer as the first electrode AE. For example, the infrared emission part NIRL and the first electrode AE can be disposed on the second planarization layer PLN2. In this configuration, the infrared emission part NIRL and the first electrode AE can be disposed to be spaced apart from each other.

Referring to FIG. 9, when the first subpixel SP1 is driven, even when light in the visible spectrum or delayed light is emitted from the second emission layer ED2_EML due to the lateral leakage current LLC flowing along the first common intermediate layer including the hole transport layer HTL in the first light emitting element ED1, since the infrared emission part NIRL absorbs the light in the visible spectrum or the delayed light and converts into light in the near-infrared spectrum, the display device 100 can provide an advantage of preventing or at least reducing the malfunction of the optical electronic device 11, which can be disposed to be partially overlapped with the infrared emission part NIRL.

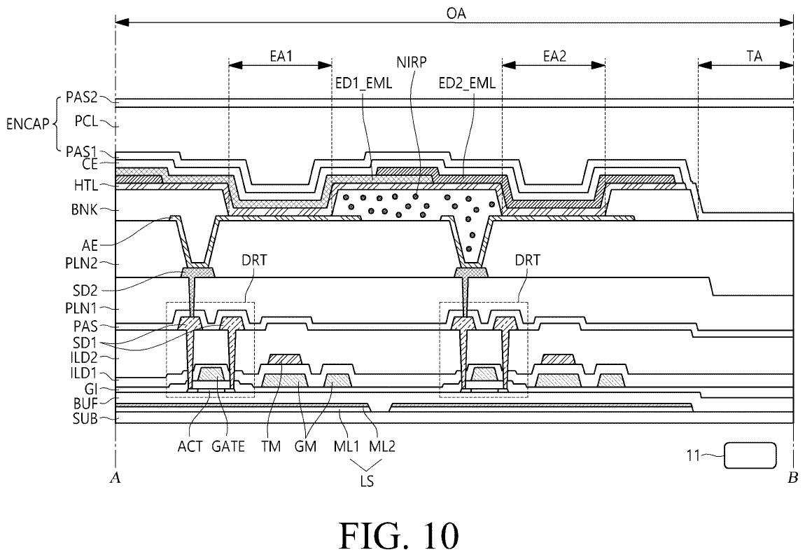

Referring to FIG. 10, in some implementations, an infrared emission part NIRL can correspond to a bank BNK including an infrared emitting material NIRP. The first emission layer ED1_EML of the first subpixel SP1 and the second emission layer ED2_EML of the second subpixel SP2 can at least partially overlap with each other on the infrared emission part NIRL. For example, at least a portion of the second emission layer ED2_EML can be disposed on at least a portion of the first emission layer ED1_EML, but implementations of the present disclosure are not limited thereto. For example, the bank BNK including the infrared emitting material NIRP, the first common intermediate layer, the first emission layer ED1_EML, and the second emission layer ED2_EML can be disposed to overlap with each other on the second planarization layer PLN2.

Referring to FIG. 10, when the second emission layer ED2_EML in an area where the first emission layer ED1_EML and the second emission layer ED2_EML overlap with each other emits downwardly due to lateral leakage current LLC, the infrared emission part NIRL disposed to be overlapped with the second emission layer ED2_EML can emit near-infrared light. For example, the light in the visible light region emitted from the second emission layer ED2_EML can be absorbed and converted into light in the near-infrared spectrum by the infrared emitting material NIRP included in the bank BNK, and thereby, the near-infrared light can be emitted.

Further, even when a light emitting element required to be turned off continuously emits light due to a difference in delay characteristics between subpixels SP, this light can be absorbed and converted into light in the near-infrared spectrum by the infrared emitting material NIRP included in the bank BNK, and thereby, the near-infrared light can be emitted.

The infrared emitting material NIRP can be included in the bank BNK with an amount of 0.25 parts by weight or more relative to 100 parts by weight of the infrared emission part NIRL including the bank BNK and the infrared emitting material NIRP. When the infrared emitting material NIRP of an amount less than the foregoing range is included in the bank BNK, it can be inefficient for light in the visible light spectrum to be converted into light in the near-infrared spectrum.

Referring to FIG. 10, when the first subpixel SP1 is driven, even when light in the visible spectrum or delayed light is emitted from the second emission layer ED2_EML due to the lateral leakage current LLC flowing along the first common intermediate layer including the hole transport layer HTL in the first light emitting element ED1, since the infrared emitting material NIRP included in the bank BNK absorbs the light in the visible spectrum or the delayed light and converts into light in the near-infrared spectrum, the display device 100 can provide an advantage of preventing or at least reducing malfunction of the optical electronic device 11, which can be disposed to be partially overlapped with the infrared emitting material NIRP.

Implementations of the present disclosure can provide a display device that is capable of preventing or reducing the leakage of light due to lateral leakage current (LLC) by including a near-infrared emission part.

Implementations of the present disclosure can provide a display device that is capable of preventing or reducing the malfunction of one or more optical sensors by including a near-infrared emission part.

Implementations of the present disclosure can provide a display device that is capable of improving the efficiency of sensing external light by one or more optical sensors by including a near-infrared emission part.

Implementations of the present disclosure can therefore provide a display device that is capable of improving the sensing performance of one or more optical sensors by preventing or reducing the leakage of light due to lateral leakage current (LLC), and thereby, reducing power consumption.

The examples and implementations described above will be briefly described as follows.

According to one or more implementations described herein, a display device includes: a substrate including a plurality of subpixels, a first electrode disposed over the substrate, a bank disposed over the substrate, covering a portion of the first electrode, and including an open area, and an infrared emission layer disposed over the substrate and at least partially overlapping with the bank.

In some implementations, the display device can further include a first common intermediate layer disposed on the first electrode and the bank, and an emission layer disposed on the first common intermediate layer. In some implementations, the plurality of subpixels can include a first subpixel including a first emission layer and a second subpixel including a second emission layer, and the first emission layer and the second emission layer can at least partially overlap with each other on the infrared emission layer.

In some implementations, at least a portion of the second emission layer can be disposed on at least a portion of the first emission layer such that the at least a portion of the second emission layer overlaps with the at least a portion of the first emission layer.

In some implementations, the first common intermediate layer can include at least one of a hole injection layer and a hole transport layer.

In some implementations, the first subpixel can have a first threshold voltage, the second subpixel can have a second threshold voltage, and the second threshold voltage can be less than the first threshold voltage.

In some implementations, the infrared emission layert can have a third threshold voltage, and the third threshold voltage can be less than the first threshold voltage and the second threshold voltage.

In some implementations, the first subpixel can have a first delay time, and the second subpixel can have a second delay time, and the second delay time can be greater than the first delay time.

In some implementations, the first delay time can be a first falling time of the first subpixel, and the second delay time can be a second falling time of the second subpixel.

In some implementations, the infrared emission layer can emit light in near-infrared spectrum having a wavelength between 700 nm and 1,100 nm.

In some implementations, the infrared emission layer can absorb light in visible light spectrum and emit light in the near-infrared spectrum.

In some implementations, the visible light spectrum absorbed by the infrared emission layer can have a wavelength between 495 nm and 570 nm.

In some implementations, the infrared emission layer can be disposed between the bank and the first common intermediate layer, and the infrared emission layer, the first emission layer, and the second emission layer can at least partially overlap with each other.

In some implementations, the bank can include an upper surface and at least one side surface, and the infrared emission layer can be disposed on the upper surface and on the at least one side surface of the bank.

In some implementations, the infrared emission layer can be spaced apart from the first electrode on at least one side surface of the bank.

In some implementations, in the display device, the infrared emission layer can be disposed between the first common intermediate layer and the emission layer, and the infrared emission layer, the first emission layer, and the second emission layer can at least partially overlap with each other.

In some implementations, a width of the infrared emission layer can be greater than or equal to a width of an area where the first emission layer and the second emission layer overlap with each other.

In some implementations, in the display device, the infrared emission layer can be disposed between the substrate and the bank, and the infrared emission layer, the first emission layer, and the second emission layer at least partially overlap with each other.

In some implementations, a width of the infrared emission layer can be greater than or equal to a width of an area where the first emission layer and the second emission layer overlap with each other.

In some implementations, the first electrode and the infrared emission layer can be disposed in a same layer, and the first electrode and the infrared emission layer can be disposed spaced apart from each other in the same layer.

In some implementations, in the display device, the infrared emission layer can correspond to the bank including an infrared emitting material.

In some implementations, in the display device, the substrate can include a normal area having a first resolution and an optical area having a second resolution lower than the first resolution, and the infrared emission layer can be disposed in the optical area.

In some implementations, the display device can further include an optical sensor disposed under the bank and at least partially overlapping with the infrared emission layer.

In some implementations, the optical sensor can be an illuminance sensor.

The examples and implementations of the present disclosure described above have been described for illustrative purposes, and those skilled in the art will appreciate that various modifications, additions and substitutions are possible, without departing from the scope and technical idea of the disclosure as disclosed in the accompanying claims. Therefore, the technical features of the present disclosure described in the above description or shown in the accompanying drawings should be interpreted as illustrative only and should not be taken as limiting the scope of the present disclosure.

What is claimed is:

1. A display device comprising:
a substrate on which a plurality of subpixels are disposed;
a first electrode disposed on the substrate;
a bank disposed over the substrate, covering a portion of the first electrode and including an open area; and
an infrared emission layer disposed over the substrate and at least partially overlapping with the bank.

2. The display device of claim 1, further comprising:
a first common intermediate layer disposed on the first electrode and disposed on the bank; and
an emission layer disposed on the first common intermediate layer,
wherein the plurality of subpixels comprise a first subpixel comprising a first emission layer and a second subpixel comprising a second emission layer, and
wherein the first emission layer and the second emission layer at least partially overlap with each other on the infrared emission layer.

3. The display device of claim 2, wherein at least a portion of the second emission layer overlaps with at least a portion of the first emission layer such that the at least a portion of the second emission layer is disposed on the at least a portion of the first emission layer.

4. The display device of claim 2, wherein the first common intermediate layer comprises at least one of a hole injection layer and a hole transport layer.

5. The display device of claim 2, wherein the first subpixel has a first threshold voltage, the second subpixel has a second threshold voltage, and the infrared emission layer has a third threshold voltage, and
wherein the second threshold voltage is less than the first threshold voltage, and the third threshold voltage is less than the first threshold voltage and the second threshold voltage.

6. The display device of claim 2, wherein the first subpixel has a first delay time, and the second subpixel has a second delay time, and
wherein the second delay time is greater than the first delay time.

7. The display device of claim 6, wherein the first delay time is a first falling time of the first subpixel, and the second delay time is a second falling time of the second subpixel.

8. The display device of claim 2, wherein the infrared emission layer emits light in near-infrared spectrum having a wavelength between 700 nm and 1,100 nm.

9. The display device of claim 8, wherein the infrared emission layer absorbs light in visible light spectrum and emits light in the near-infrared spectrum.

10. The display device of claim 9, wherein the visible light spectrum absorbed by the infrared emission layer has a wavelength between 495 nm and 570 nm.

11. The display device of claim 2, wherein:
the infrared emission layer is disposed between the bank and the first common intermediate layer; and
the infrared emission layer, the first emission layer, and the second emission layer at least partially overlap with each other.

12. The display device of claim 11, wherein:
the bank comprises an upper surface and at least one side surface; and
the infrared emission layer is spaced apart from the first electrode on the at least one side surface and is disposed on the upper surface and on the at least one side surface.

13. The display device of claim 2, wherein:
the infrared emission layer is disposed between the first common intermediate layer and the emission layer; and
the infrared emission layer, the first emission layer, and the second emission layer at least partially overlap with each other.

14. The display device of claim 13, wherein a width of the infrared emission layer is greater than or equal to a width of an area where the first emission layer and the second emission layer overlap with each other.

15. The display device of claim 2, wherein:
the infrared emission layer is disposed between the substrate and the bank; and
the infrared emission layer, the first emission layer, and the second emission layer at least partially overlap with each other.

16. The display device of claim 15, wherein a width of the infrared emission layer is greater than or equal to a width of an area where the first emission layer and the second emission layer overlap with each other.

17. The display device of claim 15, wherein:
the first electrode and the infrared emission layer are disposed in a same layer; and
the first electrode and the infrared emission layer are disposed spaced apart from each other in the same layer.

18. The display device of claim 2, wherein the infrared emission layer corresponds to the bank including an infrared emitting material.

19. The display device of claim 1, wherein:
the substrate comprises a normal area having a first resolution and an optical area having a second resolution lower than the first resolution; and
the infrared emission layer is disposed in the optical area.

20. The display device of claim 19, further comprising an optical sensor disposed under the bank and at least partially overlapping with the infrared emission layer.
